(19) United States
(12) Patent Application Publication
(10) Pub. No.: US 2026/0122935 A1
(43) Pub. Date: Apr. 30, 2026

(54) SEMICONDUCTOR PROCESSING FOR FACET SUPPRESSION OR TRAPPING IN EPITAXIAL GROWTH

(71) Applicant: TEXAS INSTRUMENTS INCORPORATED, Dallas, TX (US)

(72) Inventors: Giulio Albini, Cottonwood Heights, UT (US); Jonathan Brown, Lehi, UT (US)

(21) Appl. No.: 18/930,005

(22) Filed: Oct. 29, 2024

(51) Int. Cl. H01L 29/737; H01L 21/762; H01L 27/06; H01L 29/08; H01L 29/66

(52) U.S. Cl. CPC H10D 10/80; H10D 10/061; H10D 62/137; H10D 84/403; H10W 10/011; H10W 10/10

(57) ABSTRACT

The present disclosure relates to semiconductor processing including epitaxial growth of a semiconductor material, and more particularly for some examples, to semiconductor processing integration for a bipolar junction transistor (BJT). In an example, a device includes a semiconductor substrate, a pedestal dielectric stack over the substrate, and a BJT on the substrate. The pedestal dielectric stack includes nitrogen at an interface between first and second sub-layers of the pedestal dielectric stack. An opening is through the pedestal dielectric stack to the substrate. The opening is defined at least in part by a retrograde sidewall, which is retrograde into the pedestal dielectric stack from distal from the substrate to proximate the substrate. At least a first portion of the BJT is on an upper surface of the substrate and in the opening through the pedestal dielectric stack. At least a second portion of the BJT is over the pedestal dielectric stack.

### BACKGROUND

Integrated circuits may include bipolar junction transistors (BJTs). BJTs may be desirable for their high gain characteristics to satisfy high performance and high current drive needs. Scaling of devices in an integrated circuit to smaller nodes typically requires novel approaches to semiconductor processing for fabricating those devices. Further, integrating a BJT with other devices may complicate that semiconductor processing.

### SUMMARY

An example described herein is a semiconductor device. The semiconductor device includes a semiconductor substrate, a pedestal dielectric stack over the semiconductor substrate, and a bipolar junction transistor (BJT) on the semiconductor substrate. The pedestal dielectric stack includes nitrogen at an interface between a first sub-layer of the pedestal dielectric stack and a second sub-layer of the pedestal dielectric stack. An opening is through the pedestal dielectric stack to the semiconductor substrate. The opening is defined at least in part by a retrograde sidewall. The retrograde sidewall is retrograde into the pedestal dielectric stack from distal from the semiconductor substrate to proximate the semiconductor substrate. At least a first portion of the BJT is on an upper surface of the semiconductor substrate and in the opening through the pedestal dielectric stack. At least a second portion of the BJT further is over the pedestal dielectric stack.

Another example is a method. A dielectric stack is formed. Forming the dielectric stack includes forming a first oxide sub-layer over a semiconductor substrate, depositing a sacrificial nitride sub-layer over the first oxide sub-layer, and oxidizing the sacrificial nitride sub-layer. Oxidizing the sacrificial nitride sub-layer forms a second oxide sub-layer over the first oxide sub-layer. The dielectric stack is etched with an etchant. Etching the dielectric stack forms an opening through the dielectric stack to the semiconductor substrate. The opening is defined at least in part by a retrograde sidewall.

A further example is a method. A dielectric stack is formed. Forming the dielectric stack includes forming a first dielectric sub-layer over a semiconductor substrate, depositing a second dielectric sub-layer over the first dielectric sub-layer, and treating the second dielectric sub-layer such that a lateral etch rate of the second dielectric sub-layer to an etchant is less than a lateral etch rate of the first dielectric sub-layer to the etchant. The second dielectric sub-layer (e.g., as deposited) includes nitrogen. An opening is formed through the dielectric stack. Forming the opening includes etching the dielectric stack using the etchant.

The foregoing summary outlines rather broadly various features of examples of the present disclosure in order that the following detailed description may be better understood. Various features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIGS. 1A and 1B through FIGS. 37A and 37B are respective cross-sectional views of a semiconductor device in intermediate stages of manufacturing according to some examples.

FIGS. 38A and 38B through FIGS. 44A and 44B are respective cross-sectional views of a semiconductor device in intermediate stages of manufacturing according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. Other examples may include any permutation of including or excluding aspects or features that are described. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to semiconductor processing including epitaxial growth of a semiconductor material, and more particularly for some examples, to semiconductor processing integration for a bipolar junction transistor (BJT). Some examples include a semiconductor device including a BJT on a semiconductor substrate. A pedestal dielectric stack is over the semiconductor substrate. The pedestal dielectric stack may include nitrogen at an interface between a first sub-layer of the pedestal dielectric stack and a second sub-layer of the pedestal dielectric stack. An opening is formed through the pedestal dielectric stack to the semiconductor substrate and is defined at least in part by a retrograde sidewall. At least a portion of the BJT is on the semiconductor substrate and in the opening through the pedestal dielectric stack, and another portion of the BJT is over the pedestal dielectric stack.

More broadly, a pedestal dielectric stack is formed over a semiconductor substrate. The pedestal dielectric stack has a gradient lateral etch rate to an etchant, where a lower portion (e.g., a lower sub-layer) has a greater lateral etch rate to the etchant than a lateral etch rate to the etchant of an upper portion (e.g., an upper sub-layer). For example, multiple dielectric sub-layers may be formed over the semiconductor substrate that have the varying lateral etch rates. An opening is formed through the pedestal dielectric stack to the semiconductor substrate. The opening is formed using the etchant to etch the pedestal dielectric stack. The etchant laterally etches the lower portion faster than the upper portion, which forms a retrograde sidewall that defines at least a part of the opening. A semiconductor material may then be epitaxially grown in the opening and on the semiconductor substrate. The retrograde sidewall of the opening may remove a template effect that might cause the formation of a facet during epitaxial growth, and hence, the retrograde sidewall may suppress the formation of a facet during epitaxial growth. Further, the retrograde sidewall may have a geometric configuration that traps a facet that is formed during epitaxial growth, thereby suppressing further propagation of the facet during epitaxial growth after the trapping. By suppressing or trapping facets, subsequently epitaxially grown semiconductor material may avoid having a facet, which may improve performance of a device (e.g., a BJT) formed with the epitaxially grown material(s). Other benefits and advantages may be achieved.

The pedestal dielectric stack may be formed using any dielectric material, for example, that may achieve the lateral etch rates for forming the retrograde sidewall. Specific examples described below implement oxide sub-layers in the pedestal dielectric stack that is used in forming a BJT. The different oxide sub-layers, as described subsequently, have different lateral etch rates to achieve the retrograde sidewall. Different examples, particularly different examples implemented with different devices, may implement different dielectric material(s).

Various examples are described subsequently. Although the specific examples may illustrate various aspects of the above generally described features, examples may incorporate any combination of the above generally described features (which are described in more detail in examples below).

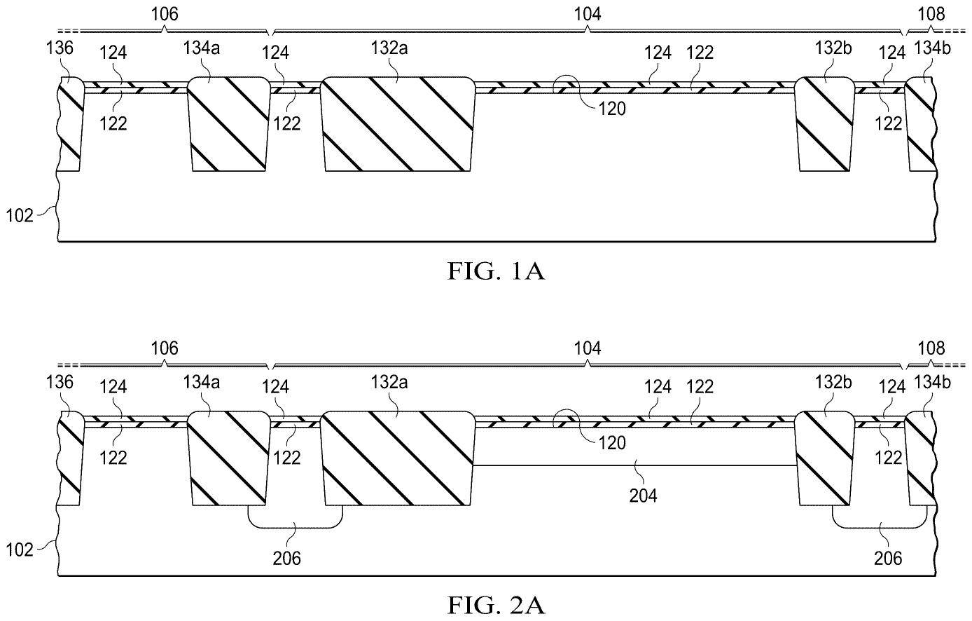

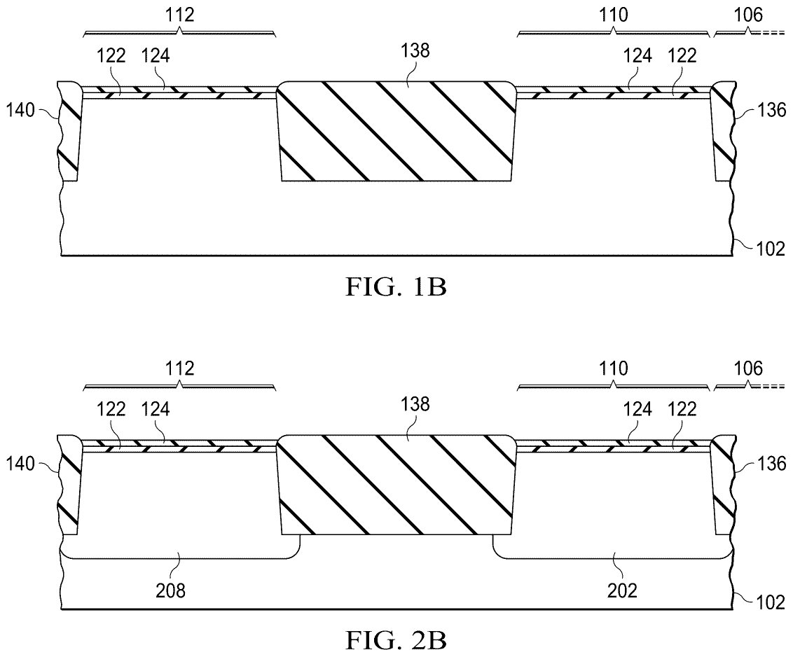

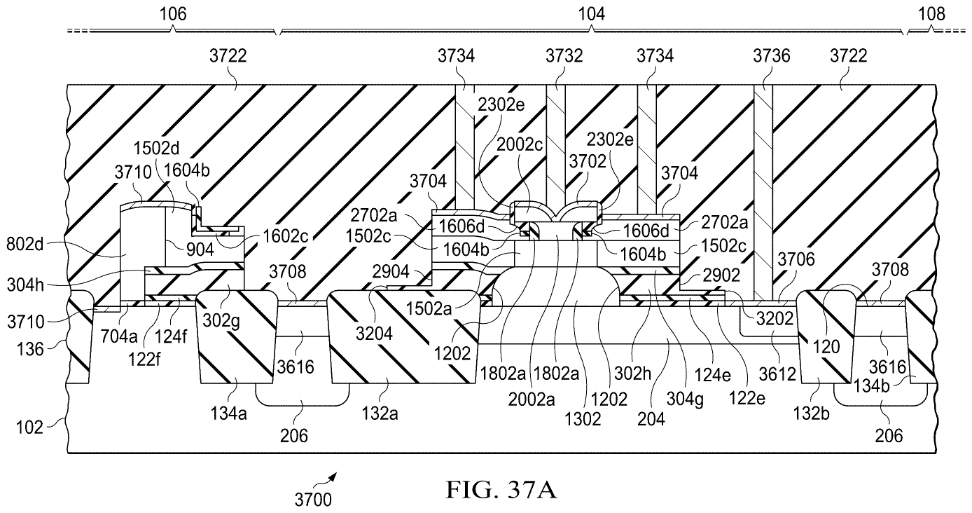

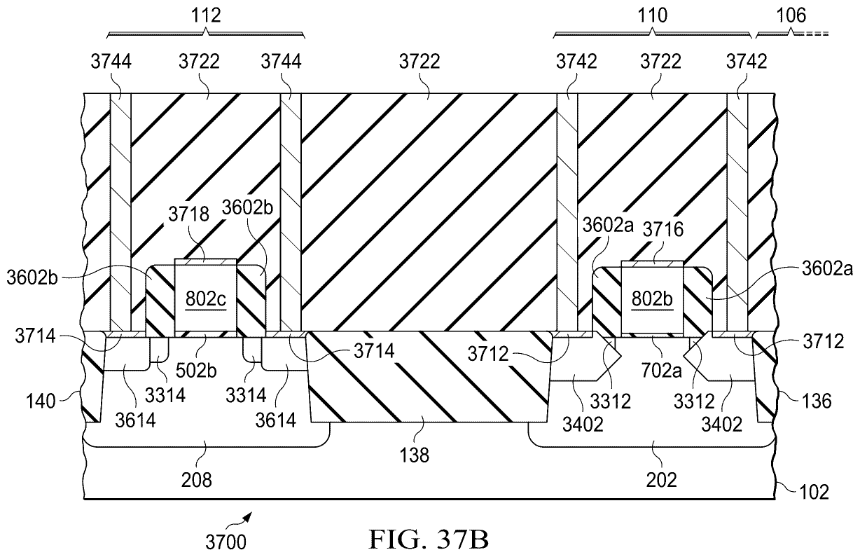

FIGS. 1A and 1B through FIGS. 37A and 37B are respective cross-sectional views of a semiconductor device in intermediate stages of manufacturing according to some examples. The method illustrated in these figures forms the semiconductor device 3700 of FIGS. 37A and 37B. As an example, a lower operating voltage rated pFET (e.g., having a lower magnitude threshold voltage) is formed in the pFET region (e.g., as illustrated by a thinner gate oxide layer subsequently), and a higher operating voltage rated nFET (e.g., having a higher magnitude threshold voltage) is formed in the nFET region (e.g., as illustrated by a thicker gate oxide layer subsequently). In other examples, a higher operating voltage rated pFET may alternatively or additionally be formed in the pFET region. In other examples, a lower operating voltage rated nFET may alternatively or additionally be formed in the nFET region.

Referring to FIGS. 1A and 1B, a semiconductor substrate 102 is provided. The semiconductor substrate 102 includes a BJT region 104, a first transition region 106, a second transition region 108, a p-type FET (pFET) region 110, and an n-type FET (nFET) region 112. Together, the pFET region 110 and the nFET region 112 are included in a complementary field effect transistor (CFET) region. In the following description and in the figures, some structures are formed in the first transition region 106. Although not illustrated and/or not described, such structures may also be formed in the second transition region 108, such as in a mirrored configuration relative to those formed in the first transition region 106. Further explicit description of such structures in the second transition region 108 is omitted for brevity.

The semiconductor substrate 102 may be or include a bulk semiconductor substrate, a semiconductor-on-insulator (SOI) substrate, or any other appropriate substrate. The semiconductor substrate 102 may also include a support (or handle) substrate and an epitaxial layer epitaxially grown on the support substrate. In some examples, the semiconductor substrate 102 is or includes a silicon substrate (which may be singulated from a bulk silicon wafer at the conclusion of semiconductor processing). In further examples, the semiconductor substrate 102 includes a silicon substrate with an epitaxial silicon layer grown thereon. The semiconductor substrate 102 is or includes a semiconductor material in and/or on which devices, such as the BJT, the pFET, and the nFET (as described subsequently), are formed. In some examples, the semiconductor material is or includes silicon (Si), silicon germanium (SiGe), gallium arsenide (GaAs), gallium nitride (GaN), the like, or a combination thereof. The semiconductor substrate 102 has an upper surface 120 in and/or on which devices (e.g., the BJT, pFET, and nFET) are formed. In the illustrated example, the semiconductor material of the semiconductor substrate 102 is p-type doped with a p-type dopant. In some examples, the semiconductor substrate 102 is p-type doped with a p-type dopant (e.g., boron (B)) with a concentration in a range from 1×10¹⁴ cm⁻³ to 1×10¹⁵ cm⁻³. Another dopant type and/or other doping concentrations may be implemented.

A first pedestal oxide sub-layer 122 is over (e.g., on) the upper surface 120 of the semiconductor substrate 102, and a second pedestal oxide sub-layer 124 is over (e.g., on) the first pedestal oxide sub-layer 122. Isolation structures 132 (including a first portion 132a and a second portion 132b), 134 (including a first portion 134a and a second portion 134b), 136, 138, 140 are formed through the first and second pedestal oxide sub-layers 122, 124 and in the semiconductor substrate 102. In the illustrated example, the isolation structures 132-140 are shallow trench isolation structures (STIs) extending from the upper surface 120 of the semiconductor substrate 102 into the semiconductor substrate 102. As illustrated, the isolation structures 132-140 are also raised above the upper surface 120 of the semiconductor substrate 102, and in other examples, the isolation structures 132-140 may have respective upper surfaces co-planar with and/or below the upper surface 120 of the semiconductor substrate 102. The isolation structures 132-140 may include, for example, a liner layer, such as including silicon oxide or silicon nitride, conformally along surfaces of a respective trench in the semiconductor substrate 102 and a fill isolation material, such as silicon oxide, over and on the liner layer.

The first pedestal oxide sub-layer 122 is formed on the upper surface of the semiconductor substrate 102. The first pedestal oxide sub-layer 122 is or includes an oxide, such as silicon oxide, formed using appropriate formation or deposition processes. In some examples, the first pedestal oxide sub-layer 122 is or includes silicon oxide formed using in situ steam generation (ISSG) oxidation, thermal oxidation, another oxidation process, or the like. The second pedestal oxide sub-layer 124 is formed on the first pedestal oxide sub-layer 122. The second pedestal oxide sub-layer 124 is or includes an oxide, such as silicon oxide, formed using appropriate formation or deposition processes. In some examples, the second pedestal oxide sub-layer 124 is or includes silicon oxide formed by a high temperature oxide (HTO) low pressure chemical vapor deposition (LPCVD) or the like.

A hardmask layer may then be deposited over the second pedestal oxide sub-layer 124. The hardmask layer may be any appropriate material, such as silicon nitride, silicon oxynitride, or the like, and may be deposited using any appropriate deposition process, such as chemical vapor deposition (CVD). The hardmask layer is patterned, such as by using photolithography and an etching process (e.g., reactive ion etch (RIE)). Recesses or trenches are etched, such as by RIE, through the first and second pedestal oxide sub-layers 122, 124 and into the semiconductor substrate 102 using the patterned hardmask layer as a mask. The liner layer may then be conformally deposited in the recesses or trenches and over the patterned hardmask layer, such as by plasma enhanced CVD (PECVD) or formed on exposed surfaces of the recesses or trenches (e.g., by an oxidation process), and the fill isolation material may be deposited over the liner layer, such as by high aspect ratio CVD (HAR-CVD), flowable CVD (FCVD), or the like. Excess fill isolation material and liner layer may be removed from over the hardmask layer by a planarization process, such as a chemical mechanical polish (CMP). The hardmask layer may then be removed by an etch selective to the hardmask layer, which may be a wet etch process. In other examples, the isolation structures 132-140 may be field oxide structures, such as local oxidation of silicon (LOCOS) structures, at the upper surface 120 of the semiconductor substrate 102, which may be formed using a LOCOS process. The isolation structures 132-140 may be further developed (e.g., by etching, oxidation, deposition, etc.) by further processing although not specifically described or illustrated.

The isolation structure 132 laterally defines an active area of the upper surface 120 of the semiconductor substrate 102 on which the BJT is to be formed. The isolation structure 132 laterally encircles or encompasses the active area of the upper surface 120 of the semiconductor substrate 102 on which the BJT is to be formed. As indicated subsequently, an active portion (e.g., a base layer) of the BJT extends laterally beyond the active area of the upper surface 120 of the semiconductor substrate 102 on which the BJT is formed and over the first portion 132a of the isolation structure 132. Further, the isolation structure 134 defines lateral boundaries of the BJT region 104. The isolation structure 134 laterally encircles or encompasses the isolation structure 132 with a doped isolation or guardring well therebetween, as described subsequently.

The isolation structures 136, 138 laterally define, at least in part, an active area of the upper surface 120 of the semiconductor substrate 102 on which the pFET is to be formed. The active area of the upper surface 120 of the semiconductor substrate 102 on which the pFET is formed defines the lateral boundary of the pFET region 110. Similarly, the isolation structures 138, 140 laterally define, at least in part, an active area of the upper surface 120 of the semiconductor substrate 102 on which the nFET is to be formed. The active area of the upper surface 120 of the semiconductor substrate 102 on which the nFET is formed defines the lateral boundary of the nFET region 112. The CFET region includes the pFET region 110 and the nFET region 112. The laterally exterior boundaries of the pFET region 110 and/or nFET region 112 (or other pFET and/or nFET regions) define the lateral boundary of the CFET region.

The first transition region 106 is defined from a lateral boundary of the BJT region 104 to a nearest lateral boundary of the CFET region (which in the illustrated example is a boundary of the pFET region 110). The first transition region 106 includes the isolation structure 136 and the first portion 134a of the isolation structure 134. As illustrated, a portion of the upper surface 120 of the semiconductor substrate 102 is between the first portion 134a of the isolation structure 134 and the isolation structure 136 in the first transition region 106. In other examples, the first transition region 106 may have an isolation structure laterally throughout the first transition region 106. The second transition region 108 is defined from a lateral boundary of the BJT region 104 to a nearest lateral boundary of another region (not illustrated). The second transition region 108 includes the second portion 134b of the isolation structure 134. The second transition region 108 may be formed and/or structured like the first transition region 106.

Referring to FIGS. 2A and 2B, an n-type doped well 202 is formed in the semiconductor substrate 102 in the pFET region 110. The n-type doped well 202 may be formed by masking (e.g., by a photoresist using photolithography) areas of the semiconductor substrate 102 where an n-type doped well is not to be formed and implanting n-type dopants into the semiconductor substrate 102. The n-type doped well 202 extends from the upper surface 120 of the semiconductor substrate 102 into a depth in the semiconductor substrate 102 and is in the pFET region 110 laterally between the isolation structures 136, 138. A concentration of the n-type dopant of the n-type doped well 202 is greater than a concentration of the p-type dopant of the p-type doped semiconductor substrate 102. In some examples, the n-type doped well 202 is doped with an n-type dopant (e.g., phosphorus (P) or arsenic (As)) with a concentration in a range from 1×10¹⁵ cm⁻³ to 1×10¹⁷ cm⁻³. Another dopant and/or other doping concentrations may be implemented.

An n-type doped sub-collector diffusion region 204 is formed in the semiconductor substrate 102 in the BJT region 104 and laterally between the portions 132a, 132b of the isolation structure 132. The n-type doped sub-collector diffusion region 204 may be formed by masking (e.g., by a photoresist using photolithography) areas of the semiconductor substrate 102 where an n-type doped sub-collector diffusion region is not to be formed and implanting n-type dopants into the semiconductor substrate 102. The n-type doped sub-collector diffusion region 204 extends from the upper surface 120 of the semiconductor substrate 102 into a depth in the semiconductor substrate 102 and is in the BJT region 104 laterally between the portions 132a, 132b of the isolation structure 132. A concentration of the n-type doped sub-collector diffusion region 204 is greater than a concentration of the p-type dopant of the semiconductor substrate 102. In some examples, the n-type doped sub-collector diffusion region 204 is doped with an n-type dopant with a concentration in a range from 1×10¹⁸ cm⁻³ to 1×10²⁰ cm⁻³. Another dopant and/or other doping concentrations may be implemented.

P-type doped wells 206, 208 are formed in the semiconductor substrate 102. The p-type doped wells 206, 208 may be formed by masking (e.g., by a photoresist using photolithography) areas of the semiconductor substrate 102 where a p-type doped well is not to be formed and implanting p-type dopants into the semiconductor substrate 102. The p-type doped well 206 extends from the upper surface 120 of the semiconductor substrate 102 into a depth in the semiconductor substrate 102 and is in the BJT region 104 laterally between the isolation structures 132, 134. The p-type doped well 206 is an isolation ring or guardring laterally encircling or encompassing the active area in which the BJT is to be formed. The p-type doped well 208 extends from the upper surface 120 of the semiconductor substrate 102 into a depth in the semiconductor substrate 102 and is in the nFET region 112 laterally between the isolation structures 138, 140. A concentration of the p-type dopant of the p-type doped wells 206, 208 is greater than a concentration of the p-type dopant of the p-type doped semiconductor substrate 102. In some examples, the p-type doped wells 206, 208 are doped with a p-type dopant with a concentration in a range from 1×10¹⁵ cm⁻³ to 1×10¹⁷ cm⁻³. Another dopant and/or other doping concentrations may be implemented.

Although the semiconductor substrate 102, n-type doped well 202, n-type doped sub-collector diffusion region 204, and p-type doped wells 206, 208 are described herein as being doped with a certain dopant conductivity type, such components may be doped with an opposite conductivity type (e.g., being n-type doped instead of p-type doped, and vice versa) in other examples. Similarly, subsequently described components that are described as being doped with a certain dopant conductivity type may also be doped with an opposite conductivity type in other examples.

As detailed subsequently, the first and second pedestal oxide sub-layers 122, 124 form part of a pedestal oxide stack that has a gradient lateral etch rate. Within the pedestal oxide stack, respective lateral etch rates of dielectric sub-layers generally increase from an upper portion of the pedestal oxide stack to a lower portion of the pedestal oxide stack (e.g., from distal from the upper surface 120 to proximate the upper surface 120). In examples in which the first pedestal oxide sub-layer 122 and the second pedestal oxide sub-layer 124 are silicon oxide formed by ISSG oxidation and HTO LPCVD, respectively, as formed or deposited on the semiconductor substrate 102, the first and second pedestal oxide sub-layers 122, 124 may have relatively low etch rates. However, the implantation to form the n-type doped sub-collector diffusion region 204 and/or any other implantation that implants dopants into the semiconductor substrate laterally between the first portion 132a and second portion 132b of the isolation structure 132 may damage the first and second pedestal oxide sub-layers 122, 124, which may increase the lateral etch rates of those sub-layers. For example, the implantation(s) may be a high dose implantation that damages the first and second pedestal oxide sub-layers 122, 124 such that the lateral etch rates of the first and second pedestal oxide sub-layers 122, 124 can be greater than the third pedestal oxide sub-layer 302 to be formed thereon as described below.

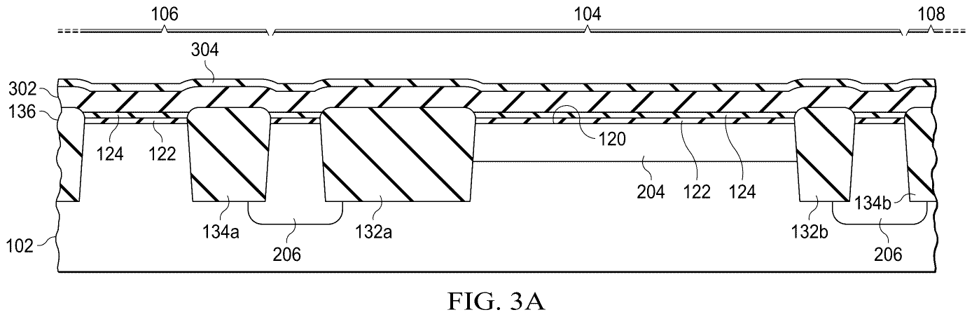

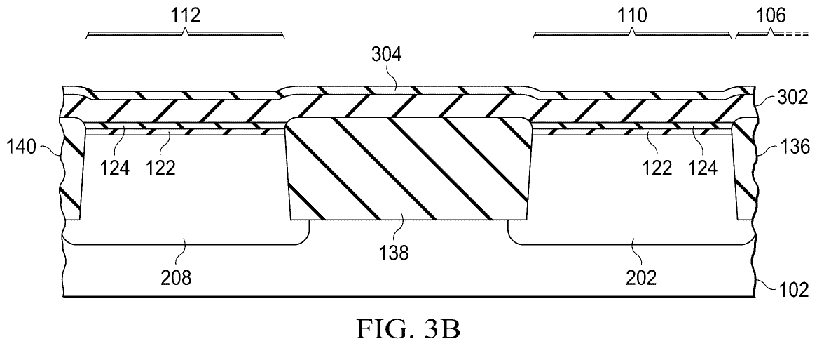

Referring to FIGS. 3A and 3B, a third pedestal oxide sub-layer 302 is formed over (e.g., on) the second pedestal oxide sub-layer 124 and the isolation structures 132-140, and a fourth pedestal sacrificial nitride sub-layer 304 is formed over (e.g., on) the third pedestal oxide sub-layer 302. The third pedestal oxide sub-layer 302 is or includes an oxide, such as silicon oxide, deposited by any appropriate deposition process. Generally, the third pedestal oxide sub-layer 302 has a lateral etch rate less than the respective lateral etch rates of the first and second pedestal oxide sub-layers 122, 124 (e.g., with having been damaged by a high dose implantation). In some examples, the third pedestal oxide sub-layer 302 is silicon oxide (e.g., a tetraethyl orthosilicate (TEOS) oxide) deposited by CVD. The fourth pedestal sacrificial nitride sub-layer 304 is or includes a nitride, such as silicon nitride, deposited by any appropriate deposition process. In some examples, the fourth pedestal sacrificial nitride sub-layer 304 is or includes silicon nitride deposited by CVD, atomic layer deposition (ALD), or the like.

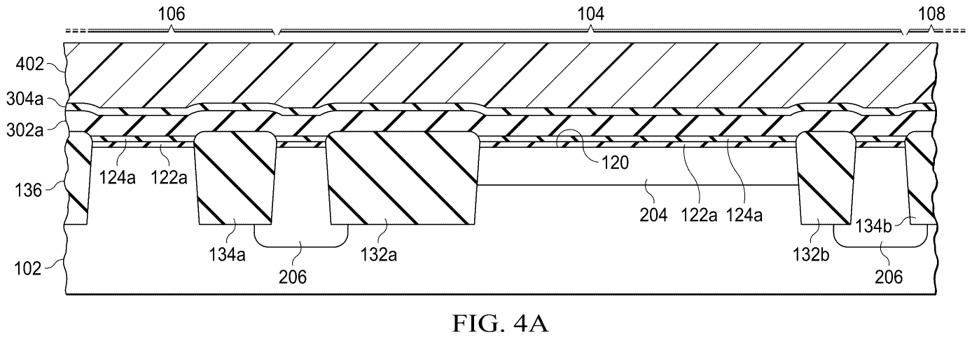

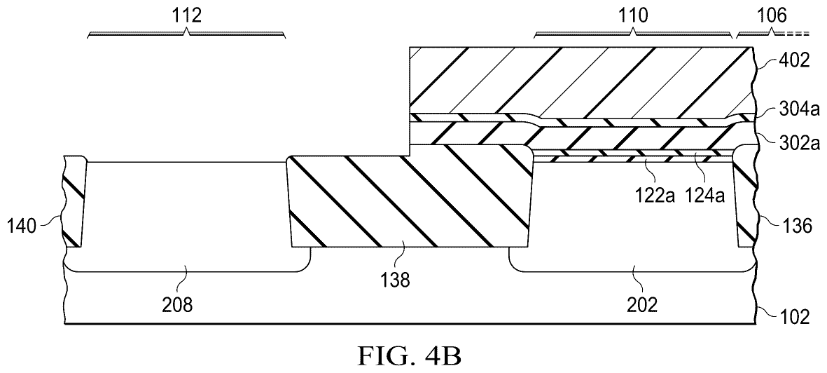

Referring to FIGS. 4A and 4B, the pedestal sub-layers 304, 302, 124, 122 are removed from the upper surface 120 of the semiconductor substrate 102 in the nFET region 112 such that the fourth pedestal sacrificial nitride sub-layer 304a, third pedestal oxide sub-layer 302a, second pedestal oxide sub-layer 124a, and first pedestal oxide sub-layer 122a remain in other regions 104-110. In the illustrated example, the portions of the pedestal sub-layers 304, 302, 124, 122 are removed using appropriate photolithography and etch processes. A photoresist 402 is deposited (e.g., by spin-on) over the fourth pedestal sacrificial nitride sub-layer 304 and patterned using photolithography. The photoresist 402 is patterned to remain in regions 104-110 in which the pedestal sub-layers 304, 302, 124, 122 are to remain and to have an opening exposing portions of layers in the nFET region 112 that are to be removed. Using the patterned photoresist 402 as a mask, an etch process, such as an anisotropic etch like an RIE or the like, is performed to remove the exposed portions of the pedestal sub-layers 304, 302, 124, 122 and to pattern the pedestal sub-layers 304a, 302a, 124a, 122a. After the etch process, the photoresist 402 is removed, such as by ashing.

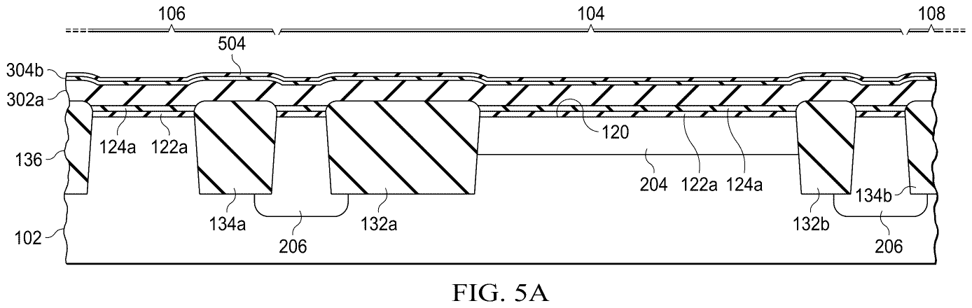

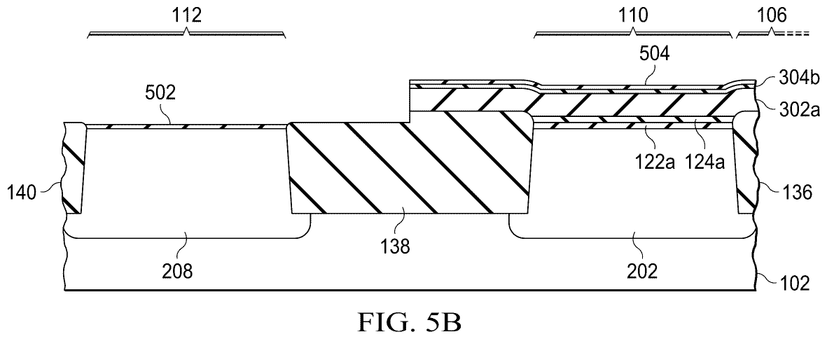

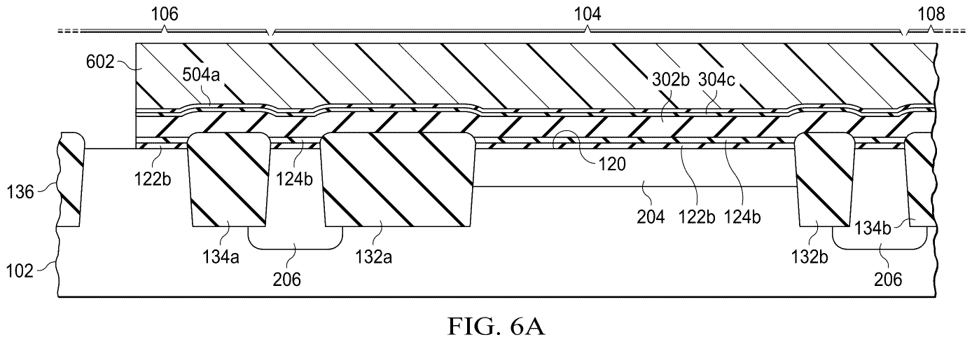

Referring to FIGS. 5A and 5B, a gate oxide layer 502 is formed over (e.g., on) the upper surface 120 of the semiconductor substrate 102 in the nFET region 112. The gate oxide layer 502 is formed using an oxidation process. Accordingly, in some examples, the gate oxide layer 502 may be an oxide, such as silicon oxide, and may be formed using ISSG oxidation or another oxidation process.

The oxidation process that forms the gate oxide layer 502 oxidizes at least an upper portion 504 of the fourth pedestal sacrificial nitride sub-layer 304a to form a fourth pedestal partial oxidized sacrificial nitride sub-layer 304b. The oxidation process may cause oxygen radicals to react with the fourth pedestal sacrificial nitride sub-layer 304a which may cause nitrogen to outgas from the fourth pedestal sacrificial nitride sub-layer 304a to form the fourth pedestal partial oxidized sacrificial nitride sub-layer 304b.

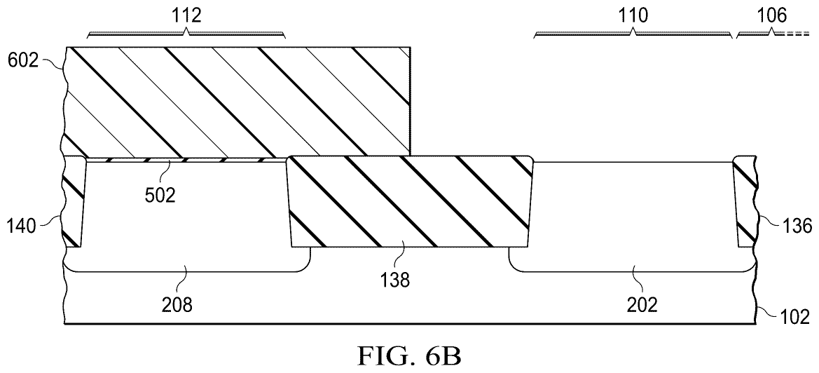

Referring to FIGS. 6A and 6B, the pedestal sub-layers 304b, 302a, 124a, 122a are removed from the upper surface 120 of the semiconductor substrate 102 in the pFET region 110 and a portion of the first transition region 106 such that the fourth pedestal partial oxidized sacrificial nitride sub-layer 304c (including the oxidized upper portion 504a), third pedestal oxide sub-layer 302b, second pedestal oxide sub-layer 124b, and first pedestal oxide sub-layer 122b remain in the BJT region 104 and portions of the transition regions 106, 108. In the illustrated example, the portions of the pedestal sub-layers 304b, 302a, 124a, 122a are removed using appropriate photolithography and etch processes. A photoresist 602 is deposited (e.g., by spin-on) over the fourth pedestal partial oxidized sacrificial nitride sub-layer 304b and patterned using photolithography. The photoresist 602 is patterned to remain in the regions 104-108 in which the pedestal sub-layers 304b, 302a, 124a, 122a are to remain and to have an opening exposing portions of layers in the pFET region 110 and first transition region 106 that are to be removed. Using the patterned photoresist 602 as a mask, an etch process, such as an anisotropic etch like an RIE or the like, is performed to remove the exposed portions of the pedestal sub-layers 304b, 302a, 124a, 122a and to pattern the fourth pedestal partial oxidized sacrificial nitride sub-layer 304c, third pedestal oxide sub-layer 302b, second pedestal oxide sub-layer 124b, and first pedestal oxide sub-layer 122b. After the etch process, the photoresist 602 is removed, such as by ashing.

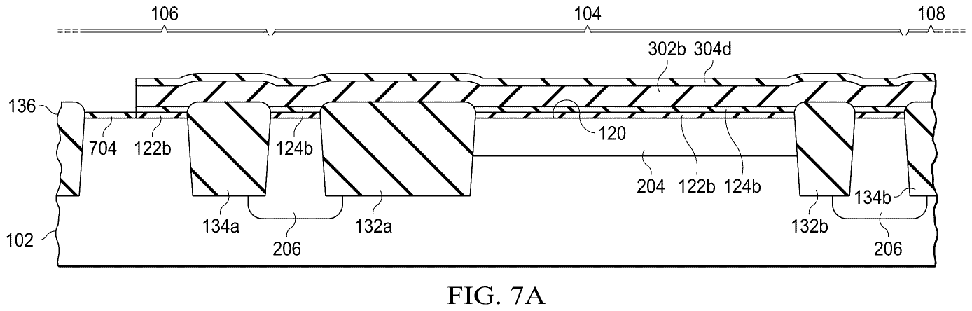

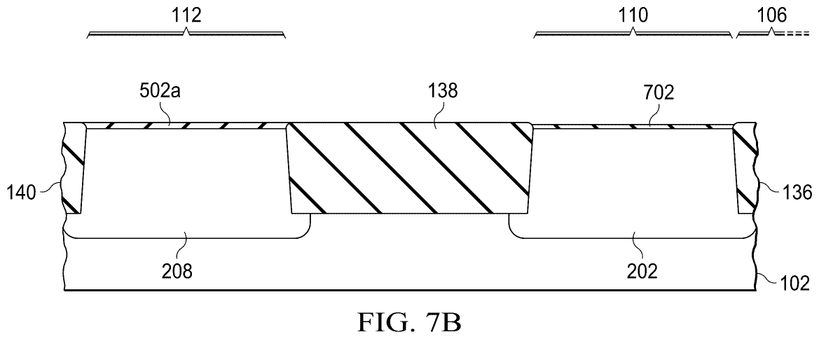

Referring to FIGS. 7A and 7B, a gate oxide layer 702 is formed over (e.g., on) the upper surface 120 of the semiconductor substrate 102 in the pFET region 110. The gate oxide layer 702 is formed using an oxidation process. Accordingly, in some examples, the gate oxide layer 702 may be an oxide, such as silicon oxide, and may be formed using ISSG oxidation or another oxidation process. Further, the oxidation process further oxidizes the gate oxide layer 502 to form a gate oxide layer 502a. The gate oxide layer 502a may therefore have a thickness that is greater than a thickness of the gate oxide layer 702. Also, the oxidation process may form an oxide layer 704 on the upper surface 120 of the semiconductor substrate 102 that is exposed in the first transition region 106.

The oxidation process that forms the gate oxide layer 702 further oxidizes the fourth pedestal partial oxidized sacrificial nitride sub-layer 304c to form a fourth pedestal oxide sub-layer 304d. The oxidation process may cause oxygen radicals to react with the fourth pedestal partial oxidized sacrificial nitride sub-layer 304c which may cause nitrogen to outgas from the fourth pedestal partial oxidized sacrificial nitride sub-layer 304c to form the fourth pedestal oxide sub-layer 304d. Although the fourth pedestal oxide sub-layer 304d is described as an oxide layer following the oxidation processes, the fourth pedestal oxide sub-layer 304d may be a partial oxidized nitride layer in other examples (e.g., that the oxidation process(es) do not fully oxidize the fourth pedestal sacrificial nitride sub-layer 304). In such examples, some nitrogen may remain in the fourth pedestal oxide sub-layer 304d at an interface between the third pedestal oxide sub-layer 302b and the fourth pedestal oxide sub-layer 304d.

In some examples, the oxidation process(es) do not penetrate the fourth pedestal sacrificial nitride sub-layer 304 to oxidize the third pedestal oxide sub-layer 302b, although in other examples, the oxidation process(es) may oxidize at least a portion of the third pedestal oxide sub-layer 302b. Oxidizing the third pedestal oxide sub-layer 302b may increase the density of the third pedestal oxide sub-layer 302b (e.g., in at least an upper portion of the third pedestal oxide sub-layer 302b) and cause an etch rate of the third pedestal oxide sub-layer 302b to be decreased. Hence, according to some examples, a thickness of the fourth pedestal sacrificial nitride sub-layer 304, as deposited in FIGS. 3A and 3B, may be selected to avoid or reduce oxidation of the third pedestal oxide sub-layer 302b by the oxidation process(es) that oxidize the fourth pedestal sacrificial nitride sub-layer 304.

In some examples, additional different gate oxide layers with different thicknesses may be formed in different regions, such as to form pFETs and/or nFETs rated for different operating voltages (e.g., in high voltage applications, medium voltage applications, or low voltage applications). In such examples, iterative processes for oxidizing the upper surface 120 of the semiconductor substrate 102 may be performed by extending the processing described with respect to FIGS. 4A and 4B through FIGS. 7A and 7B.

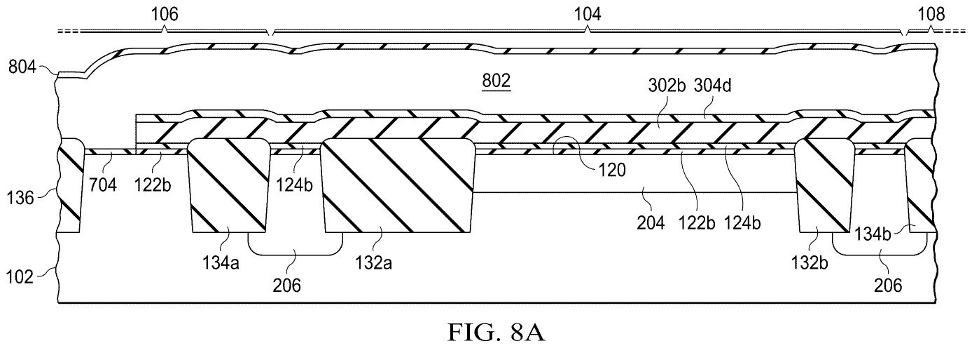

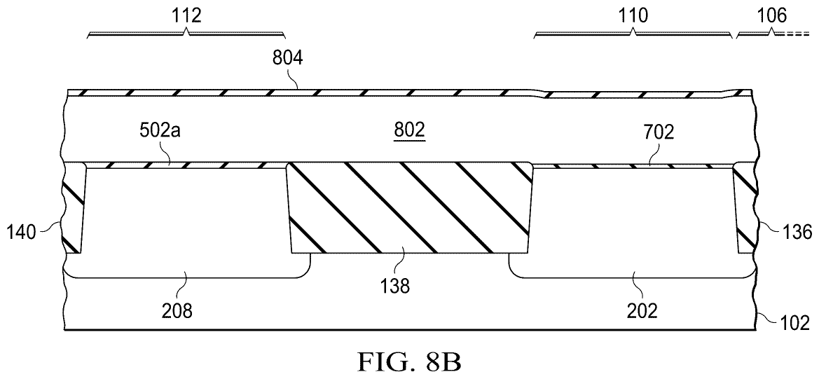

Referring to FIGS. 8A and 8B, a gate layer 802 is formed over the semiconductor substrate 102, and a dielectric protective layer 804 is formed over the gate layer 802. The gate layer 802 is formed over (e.g., on) the gate oxide layers 502a, 702, the oxide layer 704, the isolation structures 136-140, and the fourth pedestal oxide sub-layer 304d. In some examples, the gate layer 802 is or includes a semiconductor material, such as polycrystalline silicon (polysilicon), and may be formed by any deposition process, such as CVD. In some examples, the semiconductor material may be doped in situ during deposition and/or may be implanted by a dopant after deposition. For example, the gate layer 802 may be in situ doped during deposition with a p-type dopant, and after deposition, a portion of the gate layer 802 may be implanted with an n-type dopant to a greater concentration than the p-type dopant while another portion of the gate layer 802 is masked (e.g., by a photoresist formed by photolithography). In some examples, the gate layer 802 in the BJT region 104, transition regions 106, 108, and pFET region 110 is polysilicon doped with a p-type dopant with a concentration in a range from 1×10¹⁹ cm⁻³ to 1×10²¹ cm⁻³ after deposition and/or implantation, and the gate layer 802 in the nFET region 112 is polysilicon doped with an n-type dopant with a concentration in a range from 5×10¹⁹ cm⁻³ to 5×10²¹ cm⁻³ after implantation. Other materials (e.g., conductive material) may be implemented as the gate layer 802, which may be formed by any deposition process. In some examples, the dielectric protective layer 804 is silicon oxide (e.g., a TEOS oxide) deposited by CVD, although other dielectric materials and/or other deposition processes may be used in other examples.

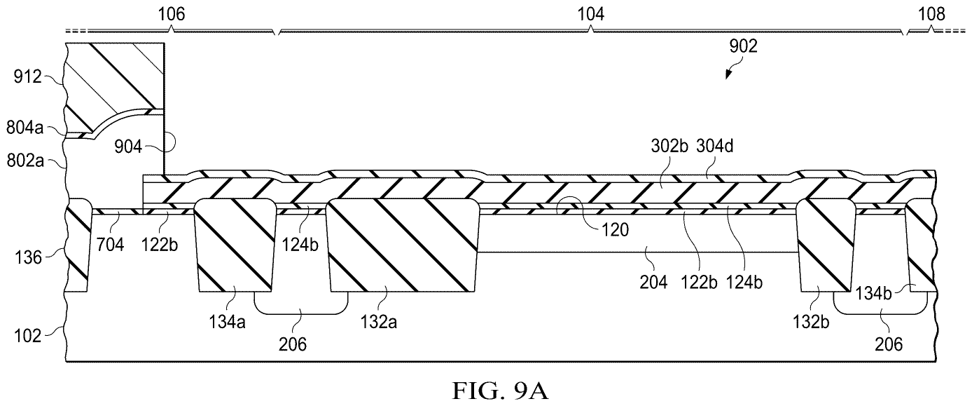

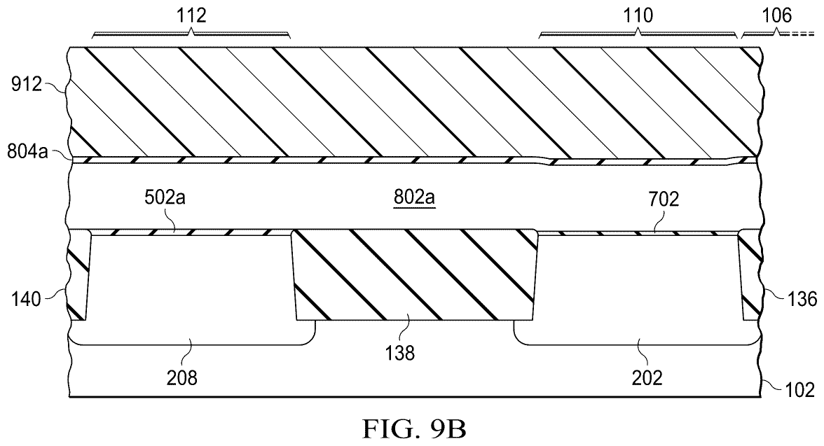

Referring to FIGS. 9A and 9B, the dielectric protective layer 804 and gate layer 802 are etched to form an opening 902 through the dielectric protective layer 804a and gate layer 802a to the fourth pedestal oxide sub-layer 304d. The opening 902 is in the BJT region 104 and the transition regions 106, 108. The formation of the opening 902 results in the dielectric protective layer 804 and the gate layer 802 being removed from the BJT region 104. The opening 902 is defined, at least in part, by a sidewall 904, of the gate layer 802a (and further by a corresponding sidewall of the dielectric protective layer 804a, which is not indicated by a reference numeral). The sidewall 904 of the gate layer 802a is over the fourth pedestal oxide sub-layer 304d in the first transition region 106. Although not illustrated, another sidewall of the gate layer 802a may be over the fourth pedestal oxide sub-layer 304d in the second transition region 108. As will be shown subsequently, the BJT is formed through the opening 902 through the gate layer 802a.

In the illustrated example, the dielectric protective layer 804 and gate layer 802 are patterned using appropriate photolithography and etch processes. A photoresist 912 is deposited (e.g., by spin-on) over the dielectric protective layer 804 and patterned using photolithography. The photoresist 912 is patterned to remain in regions in which the dielectric protective layer 804 and gate layer 802 are to remain and to have an opening corresponding to the opening 902. Using the patterned photoresist 912 as a mask, an etch process, such as an anisotropic etch like an RIE or the like, is performed to remove portions of the dielectric protective layer 804 and gate layer 802 and to pattern the dielectric protective layer 804a and gate layer 802a. As indicated by FIGS. 9A and 9B, resulting sidewalls (including the sidewall 904) of the gate layer 802a are disposed in transition regions (including transition regions 106, 108) encompassing the BJT region 104. After the etch process, the photoresist 912 is removed, such as by ashing.

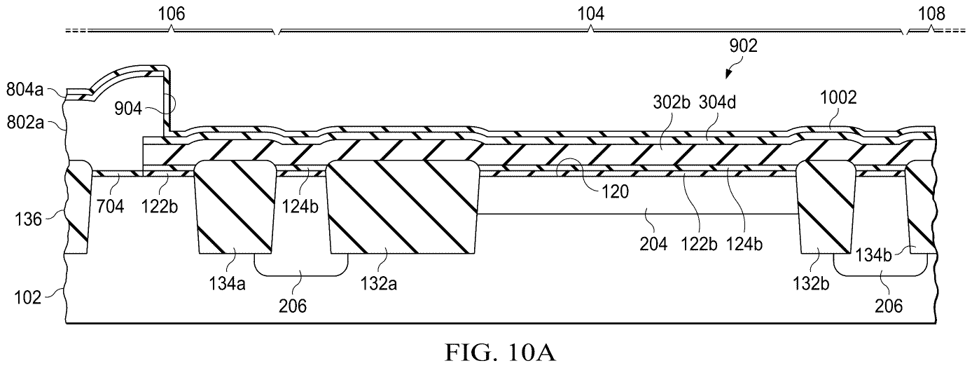

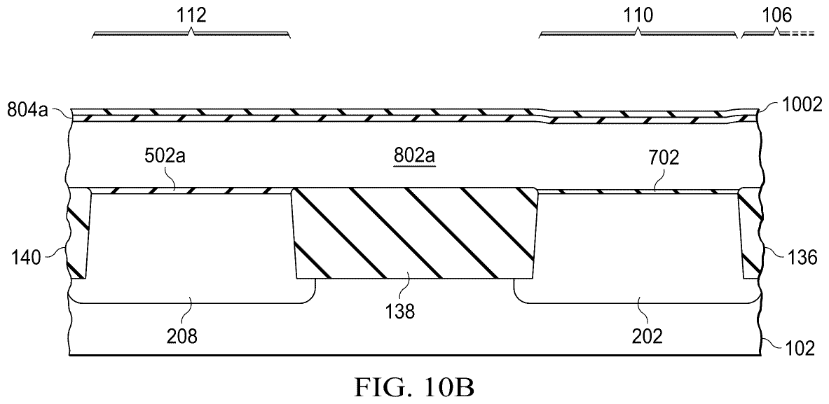

Referring to FIGS. 10A and 10B, a hardmask layer 1002 is formed conformally over the fourth pedestal oxide sub-layer 304d and the protective dielectric layer 802a. The hardmask layer 100 is formed on the sidewall 904 of the gate layer 802a in the first transition region 106. In some examples, the hardmask layer 1002 is or includes silicon nitride deposited by CVD, although other hardmask (e.g., dielectric) materials and/or other deposition processes may be used in other examples.

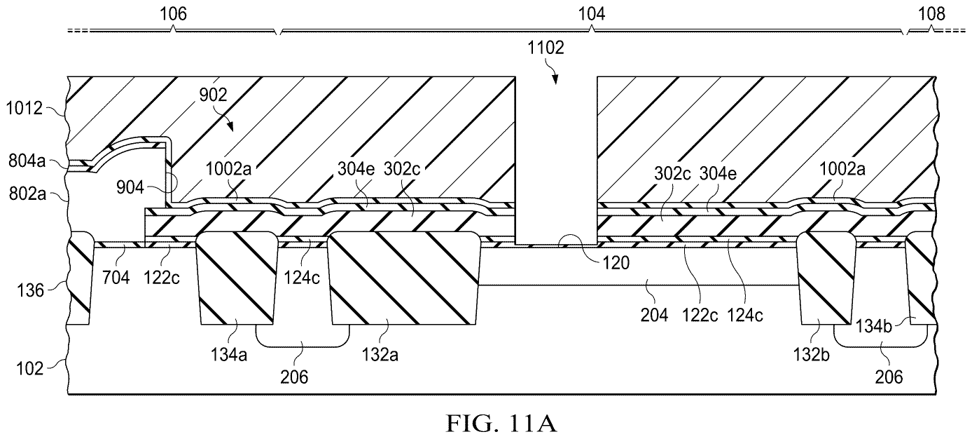

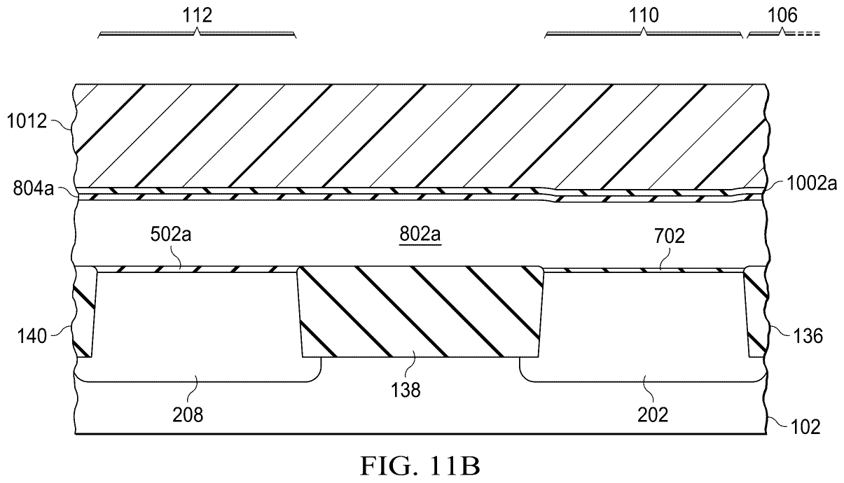

Referring to FIGS. 11A and 11B, the hardmask layer 1002 and the pedestal oxide sub-layers 304d, 302b, 124b, 122b are etched to form a collector recess 1102 through the hardmask layer 1002a, the fourth pedestal oxide sub-layer 304c, the third pedestal oxide sub-layer 302c, and the second pedestal oxide sub-layer 124c to and/or into the first pedestal oxide sub-layer 122c. The collector recess 1102 is formed in the BJT region 104 laterally over the n-type doped sub-collector diffusion region 204 between the first portion 132a and the second portion 132b of the isolation structure 132. In the illustrated example, the collector recess 1102 is formed using appropriate photolithography and etch processes. A photoresist 1012 (e.g., a tri-layer photoresist structure) is deposited (e.g., by spin-on) on or over the hardmask layer 1002 and patterned using photolithography. The photoresist 1012 is patterned to have an opening corresponding to the collector recess 1102. Using the patterned photoresist 1012 as a mask, an etch process, such as an anisotropic etch like an RIE or the like, is performed to etch the hardmask layer 1002 and the pedestal oxide sub-layers 304d, 302b, 124b, 122b. After the etch process, the photoresist 1012 is removed, such as by ashing. A portion of the first pedestal oxide sub-layer 122c may remain over the upper surface 120 of the semiconductor substrate 102 under the collector recess 1102. In some examples, the collector recess 1102 may be an opening that exposes the upper surface 120 of the semiconductor substrate 102.

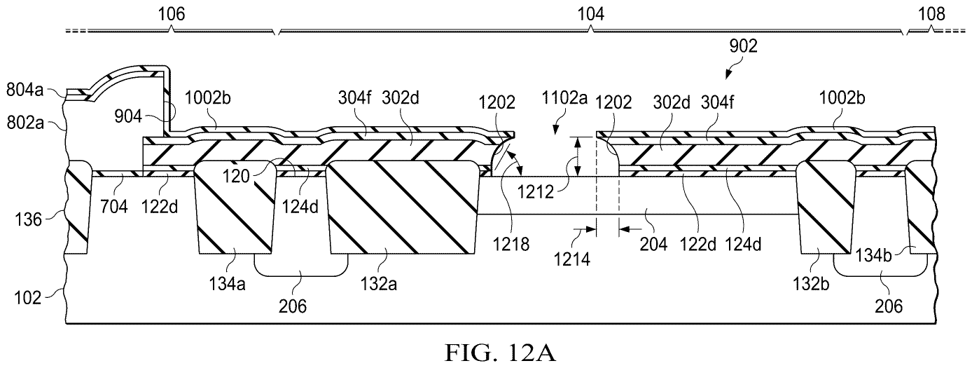

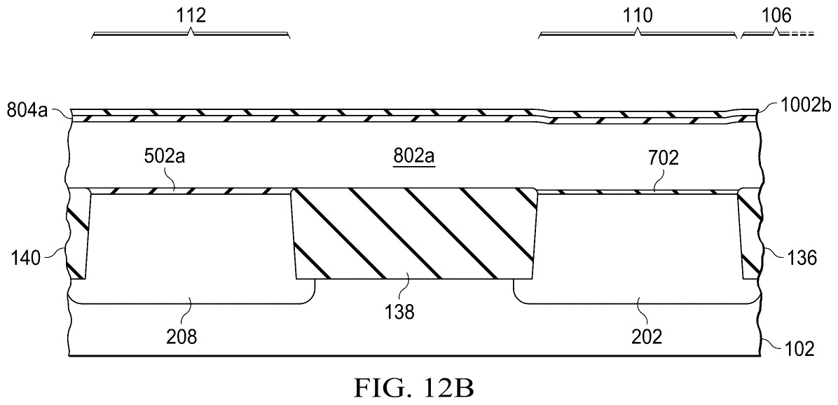

Referring to FIGS. 12A and 12B, an etch process that includes a lateral etch component is performed that etches the pedestal oxide sub-layers 304c, 302c, 124c, 122c at the collector recess 1102 and forms a collector opening 1102a through the fourth pedestal oxide sub-layer 304f, the third pedestal oxide sub-layer 302d, the second pedestal oxide sub-layer 124d, and the first pedestal oxide sub-layer 122d. The etch process may be an isotropic etch process, such as a wet etch process. In examples in which the pedestal oxide sub-layers 304c, 302c, 124c, 122c are silicon oxide, the etch process includes using an etching including hydrofluoric (HF) acid. For example, the etch process may use or be diluted hydrofluoric (dHF) acid, a buffered oxide etch (BOE), or the like. The etch process etches through the first pedestal oxide sub-layer 122c to expose the upper surface 120 of the semiconductor substrate 102 through the collector opening 1102a and laterally etches the pedestal oxide sub-layers 304e, 302c, 124c, 122c to form retrograde sidewalls 1202 in the pedestal oxide sub-layers 304f, 302d, 124d, 122d that define, at least in part, the collector opening 1102a. Each retrograde sidewall 1202 is retrograde into the pedestal oxide sub-layers 304f, 302d, 124d, 122d from a distance distal from the upper surface 120 of the semiconductor substrate 102 towards the upper surface 120. The collector opening 1102a is generally proximate to (or some lateral distance from) the first portion 132a of the isolation structure 132 and over the n-type doped sub-collector diffusion region 204 in the BJT region 104.

The retrograde sidewalls 1202 may be formed as a result of different lateral etch rates of the pedestal oxide sub-layers 304c, 302c, 124c, 122c to the etchant of the etch process. In some examples, respective lateral etch rates to the etchant of the first pedestal oxide sub-layer 122c and the second pedestal oxide sub-layer 124c are greater than the lateral etch rate to the etchant of the third pedestal oxide sub-layer 302c, and the etch rate of the third pedestal oxide sub-layer 302c is greater than the lateral etch rate to the etchant of the fourth pedestal oxide sub-layer 304c. In some examples, the first pedestal oxide sub-layer 122, as initially formed on the semiconductor substrate 102, may be a high density silicon oxide formed by an oxidation process, which may have a low lateral etch rate to the etchant, and the second pedestal oxide sub-layer 124, as initially deposited over the semiconductor substrate 102, may be a high density silicon oxide deposited by HTO-LPCVD, which may also have a low lateral etch rate to the etchant. However, in such examples, a subsequent implantation (e.g., a high dose implantation) may damage the first and second pedestal oxide sub-layers 122, 124 such that the first and second pedestal oxide sub-layers 122, 124 have a higher lateral etch rate to the etchant of the etch process in FIG. 12A. Hence, during the etch process, more of the first and second pedestal oxide sub-layers 122c, 124c may be laterally etched from sidewalls of the collector recess 1102 than the third and fourth pedestal oxide sub-layers 302c, 304c, and more of the third pedestal oxide sub-layer 302c may be laterally etched from sidewalls of the collector recess 1102 than the fourth pedestal oxide sub-layer 304c. The lower lateral etch rate of the fourth pedestal oxide sub-layer 304c may maintain a lateral width and/or length of the collector opening 1102a at the fourth pedestal oxide sub-layer 304e to be approximately equal to the respective lateral width and/or length of the collector recess 1102.

Forming the retrograde sidewalls 1202 may, in some examples, remove a template effect, which may suppress facet formation during subsequent epitaxial growth in the collector opening 1102a. In some examples, the upper surface 120 is a monocrystalline surface with a (001) or (100) surface orientation, and the retrograde sidewalls 1202 have a (110) surface orientation. With vertical sidewalls in such a situation, a template effect may cause a facet with a (111) surface orientation to be formed during subsequent epitaxial growth in a collector opening. With the retrograde sidewalls 1202, the templating effect may be removed, and formation of such facets may be suppressed.

In some examples, the retrograde sidewalls 1202 may trap a facet that is formed during subsequent epitaxial growth in the collector opening 1102a. Any portion of the retrograde sidewall 1202 may have a geometric configuration that may trap a facet. For such a portion, a ratio of a vertical dimension from a lower retrograde portion to an upper overhang portion to a lateral dimension from the lower retrograde portion to the upper retrograde portion is such that a facet may be trapped. For example, as illustrated, the retrograde sidewall 1202 has a vertical dimension 1212 from a lower retrograde portion (e.g., a lower point in the retrograde sidewall 1202) to an upper overhang portion (e.g., an upper point in the retrograde sidewall 1202 relative to the lower point) and has a lateral dimension 1214 from the lower retrograde portion to the upper retrograde portion. The vertical dimension 1212 is orthogonal to the upper surface 120 of the semiconductor substrate 102, and the lateral dimension 1214 is parallel to the upper surface 120 of the semiconductor substrate 102. The vertical dimension 1212 and lateral dimension 1214 form an angle 1218 between the upper surface 120 of the semiconductor substrate 102 and a line from the lower retrograde portion to the upper overhang portion. The angle 1218 is laterally interior to the collector opening 1102a. The angle 1218 is the inverse tangent of the ratio of the vertical dimension 1212 to the lateral dimension 1214

$$( e . g . , {θ}_{1218} = {tan}^{- 1} ( \frac{{V}_{1212}}{{L}_{1214}} ) ,$$

where θ₁₂₁₈ is the angle 1218, V₁₂₁₂ is the vertical dimension 1212, and L₁₂₁₄ is the lateral dimension 1214). In some examples, the lateral dimension 1214 is equal to or greater than 10 nm, such as equal to or greater than 20 nm.

The angle 1218 (and hence, the ratio of the vertical dimension 1212 to the lateral dimension 1214) is such that a facet formed in a subsequent epitaxial growth is trapped by the retrograde sidewall 1202. For example, when the upper surface 120 is a (001) or (100) plane of monocrystalline silicon and silicon is epitaxially grown on the upper surface 120, the silicon epitaxially grown may have a facet with a (111) surface orientation. In such an example, the angle 1218 may be equal to or less than 54.7° (e.g., equal to or less than 54°). Correspondingly, the ratio of the vertical dimension 1212 to the lateral dimension 1214 may be equal to or less than 1.376. With such an angle 1218, the facet with a (111) surface orientation may intersect the retrograde sidewall 1202 when the silicon is grown to a sufficient thickness, which may cause propagation of the facet to be arrested in subsequent epitaxial growth. The angle 1218 may be another angle depending on, e.g., which surface orientation of a facet may be trapped by the retrograde sidewall 1202.

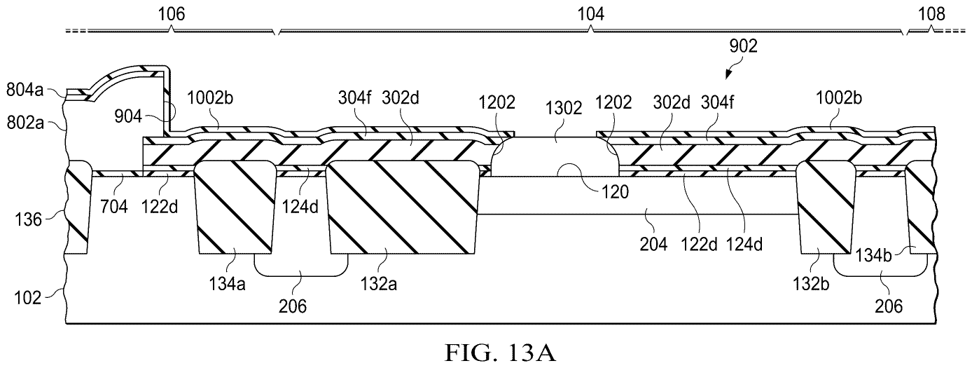

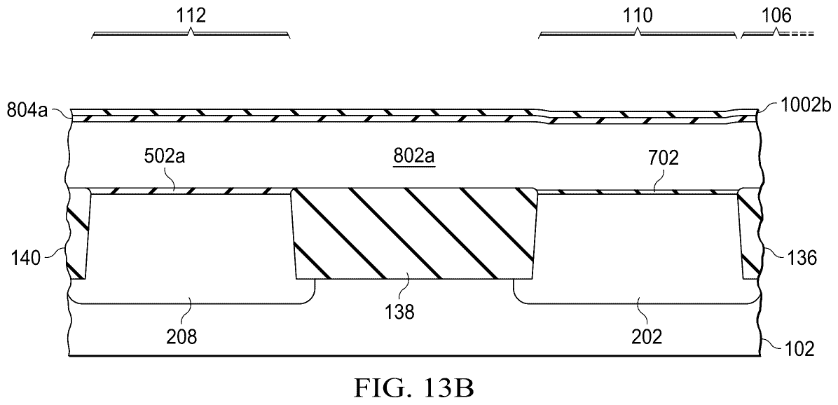

Referring to FIGS. 13A and 13B, a collector layer 1302 is formed over (e.g., on) the upper surface 120 of the semiconductor substrate 102 and in the collector opening 1102a. In some examples, the collector layer 1302 is or includes a semiconductor layer doped with an n-type dopant (e.g., a same dopant type as the n-type doped sub-collector diffusion region 204). In some examples, the collector layer 1302 is or includes silicon. In some examples, the collector layer 1302 is doped with an n-type dopant with a concentration in a range from 1×10¹⁹ cm⁻³ to 1×10²¹ cm⁻³. The collector layer 1302 may be epitaxially grown on the upper surface 120 of the semiconductor substrate 102. The collector layer 1302 may be epitaxially grown by a selective epitaxial growth process in some examples. The epitaxial growth of the collector layer 1302 on the upper surface 120 of the semiconductor substrate 102 may result in the collector layer 1302 being monocrystalline. Further, the collector layer 1302 may be in situ doped during the epitaxial growth process (e.g., the selective epitaxial growth process). The epitaxial growth process may be a CVD process, such as a LPCVD, reduced pressure CVD (RPCVD), metal organic CVD (MOCVD), or the like. The retrograde sidewalls 1202 of the collector opening 1102a may suppress (e.g., including trapping) facet growth and/or propagation during epitaxial growth of the collector layer 1302. Hence, an upper surface of the collector layer 1302 may replicate the upper surface 120 of the semiconductor substrate 102. Other materials, dopant type, dopant concentration, and/or deposition process may be implemented.

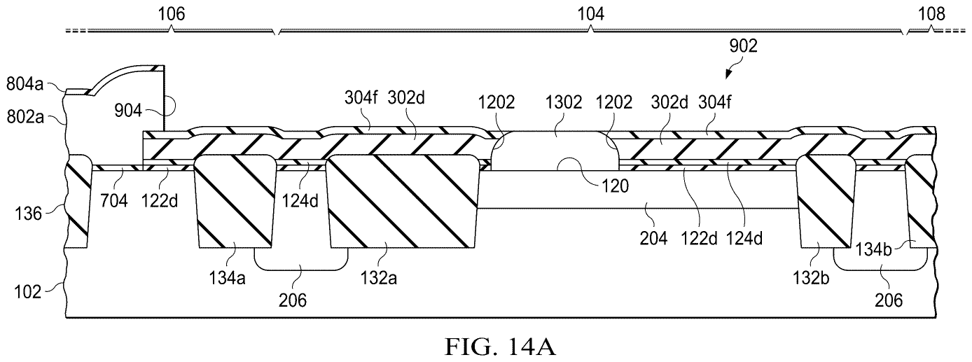

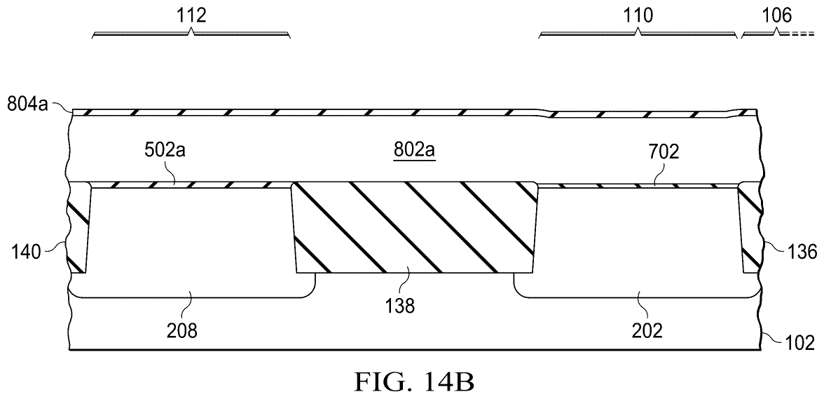

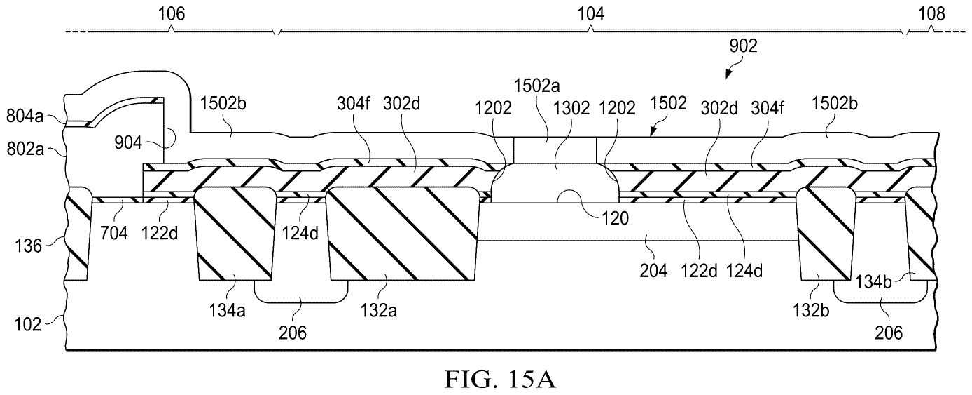

Referring to FIGS. 14A and 14B, the hardmask layer 1002b is removed. The hardmask layer 1002b may be removed using an etch selective to the material of the hardmask layer 1002b. The etch process may be a wet or dry etch process and may be isotropic. For example, when the hardmask layer 1002b is silicon nitride, the etch process may be or include using phosphoric (H₃PO₄) acid.

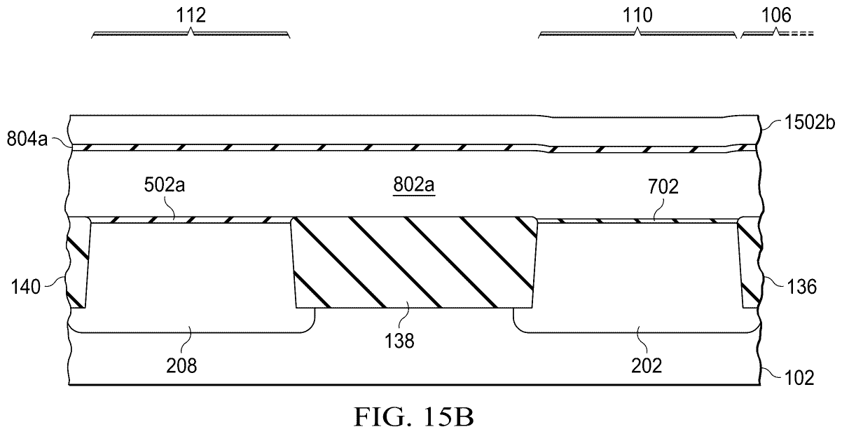

Referring to FIGS. 15A and 15B, a base layer 1502 is formed over the collector layer 1302. The base layer 1502 includes a monocrystalline base layer 1502a and a polycrystalline base layer 1502b. The monocrystalline base layer 1502a and polycrystalline base layer 1502b together form the base layer 1502. In some examples, the base layer 1502 is or includes a semiconductor layer doped with a p-type dopant (e.g., an opposite dopant type as the collector layer 1302). In some examples, the base layer 1502 is or includes silicon germanium. In some examples, the base layer 1502 is doped with a p-type dopant with a concentration in a range from 1×10¹⁷ cm⁻³ to 1×10²¹ cm⁻³. The base layer 1502 may also be doped with carbon (C) to prevent or reduce diffusion of the p-type dopant. The base layer 1502 may be epitaxially grown on the collector layer 1302 and conformally on the fourth pedestal oxide sub-layer 304f, the dielectric protective layer 804a, and the sidewall 904 of the gate layer 802a. The base layer 1502 may be epitaxially grown by a non-selective epitaxial growth process in some examples. The non-selective epitaxial growth process grows the monocrystalline base layer 1502a from the collector layer 1302 and grows the polycrystalline base layer 1502b on other amorphous or polycrystalline surfaces, such as the fourth pedestal oxide sub-layer 304f and the dielectric protective layer 804a. The monocrystalline base layer 1502a may meet the polycrystalline base layer 1502b at a facet that is not specifically illustrated. The non-selective deposition of the base layer 1502 forms the base layer 1502 conformally. The base layer 1502 may be in situ doped during the epitaxial growth process. The base layer 1502 (e.g., the monocrystalline base layer 1502a and polycrystalline base layer 1502b each) may further include multiple sub-layers, such as a nucleation sub-layer of the same material as the collector layer 1302, an undoped sub-layer, a doped sub-layer, and a cap sub-layer of the same material of the emitter layer (described subsequently). The epitaxial growth process may be a CVD process, such as LPCVD, RPCVD, MOCVD, or the like. Other materials, dopant type, dopant concentration, and/or deposition process may be implemented.

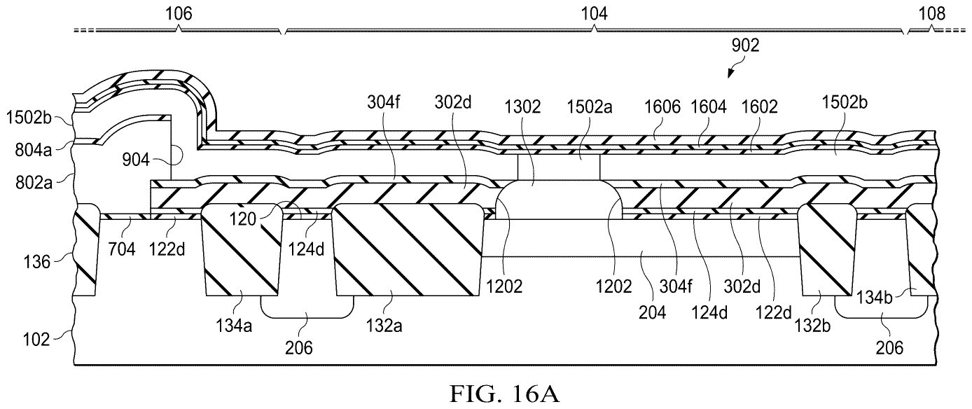

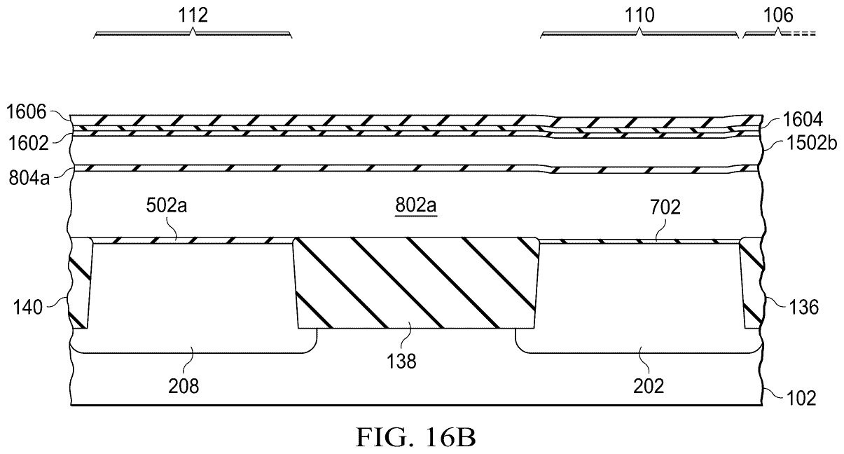

Referring to FIGS. 16A and 16B, a first dielectric spacer layer 1602 is formed conformally over the base layer 1502. A second dielectric spacer layer 1604 is formed conformally over the first dielectric spacer layer 1602, and a third dielectric spacer layer 1606 is formed conformally over the second dielectric spacer layer 1604. In some examples, the first dielectric spacer layer 1602 and third dielectric spacer layer 1606 are a same dielectric material, and the second dielectric spacer layer 1604 is a dielectric material different from the dielectric material of the first dielectric spacer layer 1602 and third dielectric spacer layer 1606. In some examples, the first dielectric spacer layer 1602 and third dielectric spacer layer 1606 are silicon oxide (e.g., a TEOS oxide), and the second dielectric spacer layer 1604 is silicon nitride. The dielectric spacer layers 1602-1606 may be deposited by CVD. Other dielectric materials and/or other deposition processes may be used in other examples.

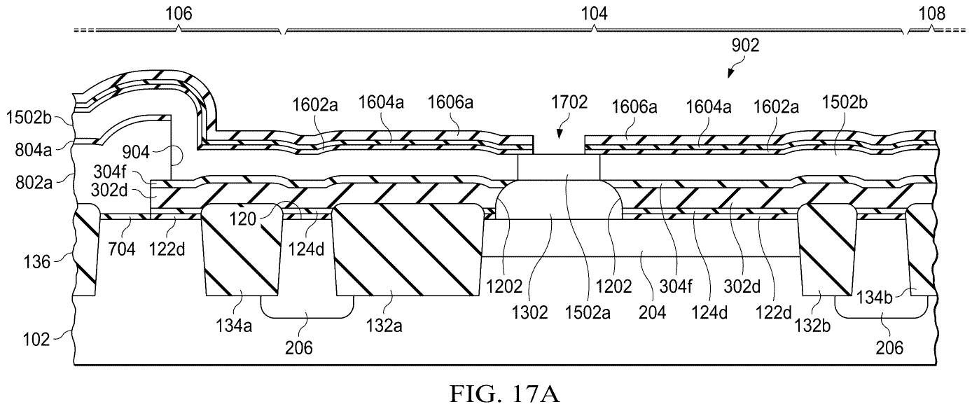

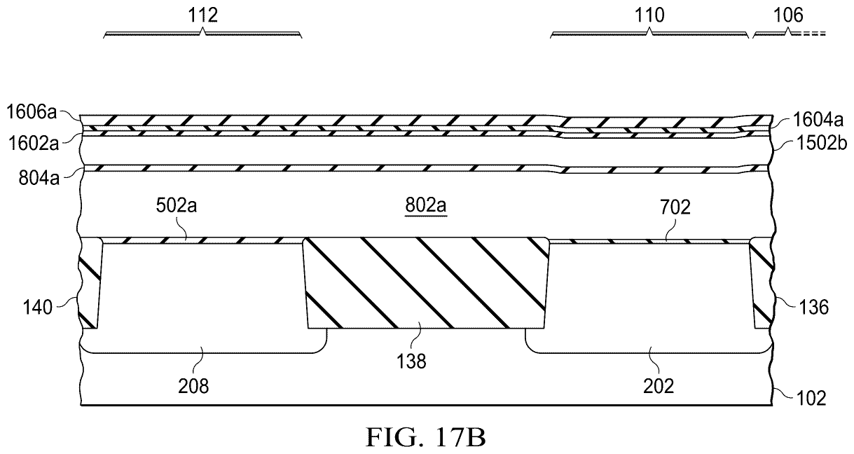

Referring to FIGS. 17A and 17B, the dielectric spacer layers 1602-1606 are etched to form a first emitter opening 1702 in the BJT region 104 through the first dielectric spacer layer 1602a, second dielectric spacer layer 1604a, and third dielectric spacer layer 1606a. The monocrystalline base layer 1502a (of the base layer 1502) is exposed through the first emitter opening 1702. The dielectric spacer layers 1602-1606 may be patterned using appropriate photolithography and etch (e.g., RIE) processes.

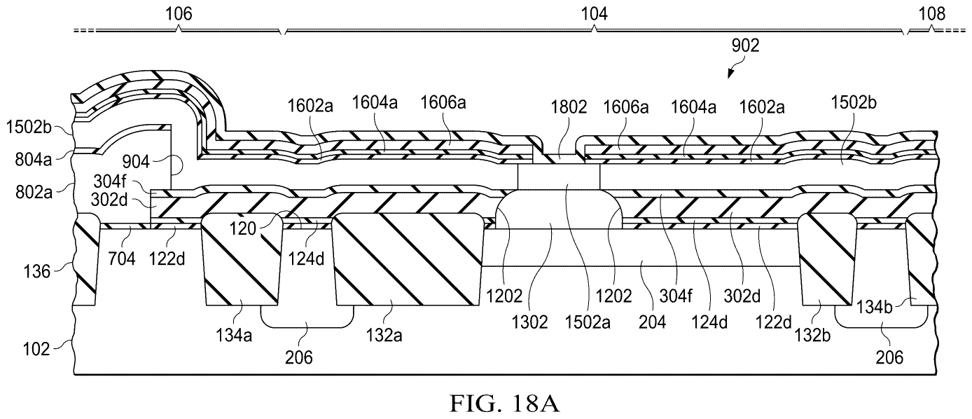

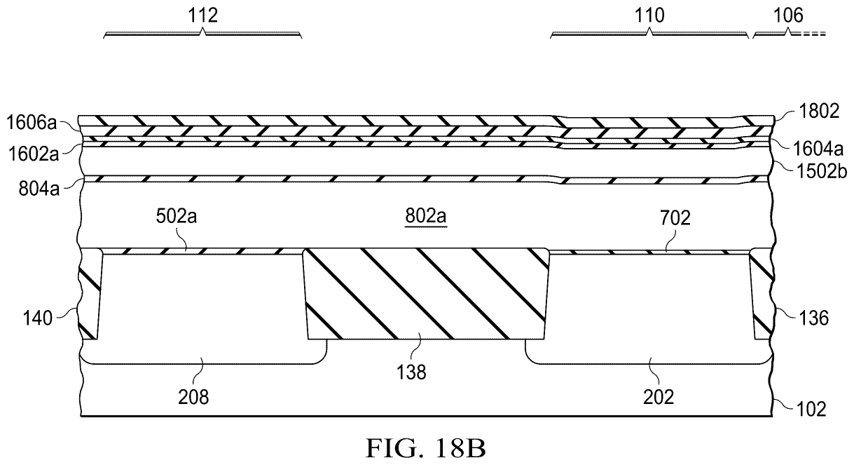

Referring to FIGS. 18A and 18B, an emitter dielectric spacer layer 1802 is conformally formed over the third dielectric spacer layer 1606a and in the first emitter opening 1702. In some examples, the emitter dielectric spacer layer 1802 is silicon oxide (e.g., a TEOS oxide) deposited by CVD, although other dielectric materials and/or other deposition processes may be used in other examples.

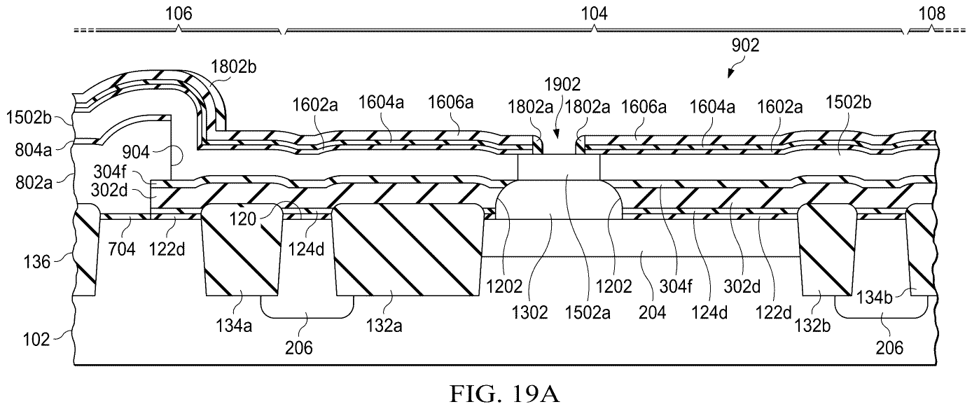

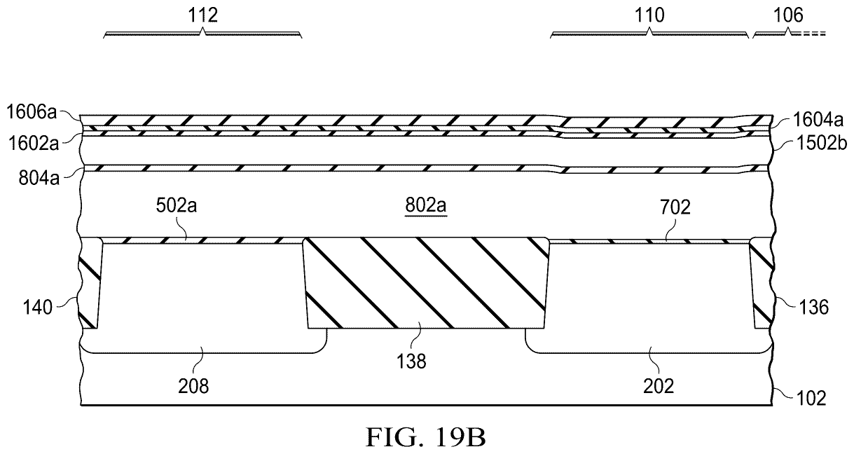

Referring to FIGS. 19A and 19B, the emitter dielectric spacer layer 1802 is anisotropically etched to form emitter dielectric spacers 1802a along sidewalls of the dielectric spacer layers 1602a, 1604a, 1606a that define the first emitter opening 1702. The emitter dielectric spacers 1802a constrict the first emitter opening 1702 to form a second emitter opening 1902. Additionally, residual dielectric spacers 1802b may remain on respective vertical surfaces, such as a vertical surface at the sidewall 904 of the gate layer 802a in the first transition region 106. The anisotropic etch may be an RIE, for example.

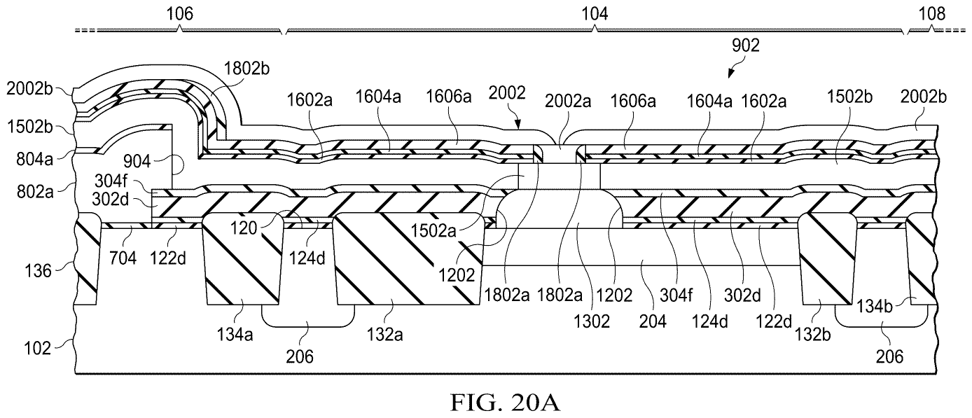

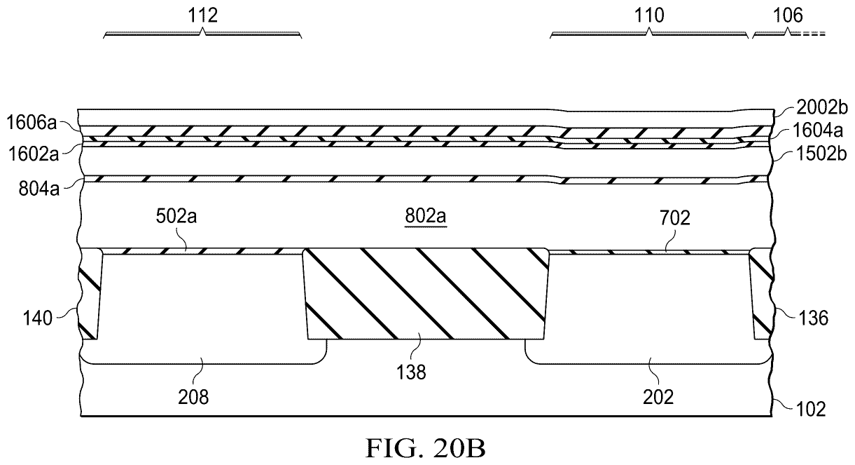

Referring to FIGS. 20A and 20B, an emitter layer 2002 is formed over the base layer 1502 (e.g., on the monocrystalline base layer 1502a). The emitter layer 2002 includes a monocrystalline emitter layer 2002a and a polycrystalline emitter layer 2002b. The monocrystalline emitter layer 2002a and polycrystalline emitter layer 2002b together form the emitter layer 2002. In some examples, the emitter layer 2002 is or includes a semiconductor layer doped with an n-type dopant (e.g., an opposite dopant type from the base layer 1502). In some examples, the emitter layer 2002 is or includes silicon. In some examples, the emitter layer 2002 is doped with an n-type dopant with a concentration in a range from 1×10¹⁹ cm⁻³ to 1×10²¹ cm⁻³. The emitter layer 2002 may be epitaxially grown on the base layer 1502 (e.g., the monocrystalline base layer 1502a) exposed through the second emitter opening 1902, the emitter dielectric spacers 1802a, the third dielectric spacer layer 1606a, and the residual dielectric spacer 1802b. The emitter layer 2002 may be epitaxially grown by a non-selective epitaxial growth process in some examples. The non-selective epitaxial growth process grows the monocrystalline emitter layer 2002a from the monocrystalline base layer 1502a and grows the polycrystalline emitter layer 2002b on other amorphous or polycrystalline surfaces, such as the emitter dielectric spacers 1802a, the third dielectric spacer layer 1606a, and the residual dielectric spacer 1802b. The monocrystalline emitter layer 2002a may meet the polycrystalline emitter layer 2002b at a facet that is not specifically illustrated. The non-selective deposition of the emitter layer 2002 forms the emitter layer 2002 conformally. The emitter layer 2002 may be in situ doped during the epitaxial growth process. The epitaxial growth process may be a CVD process, such as LPCVD, RPCVD, MOCVD, or the like. Other materials, dopant type, dopant concentration, and/or deposition process may be implemented.

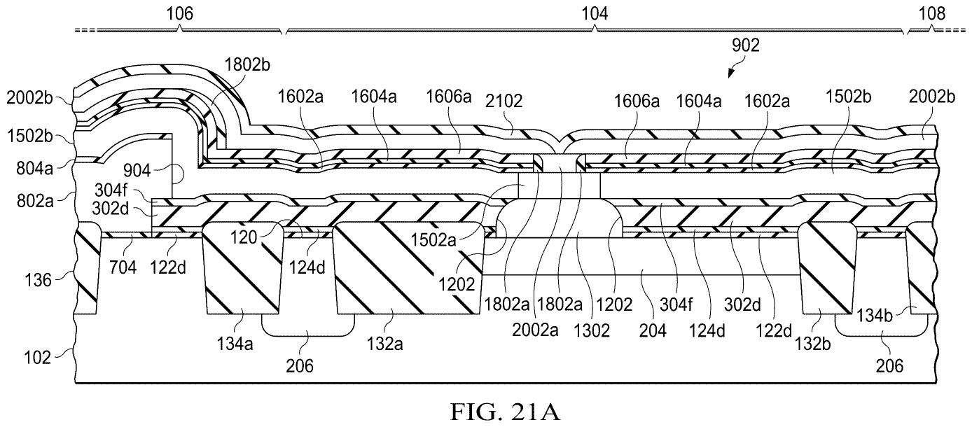

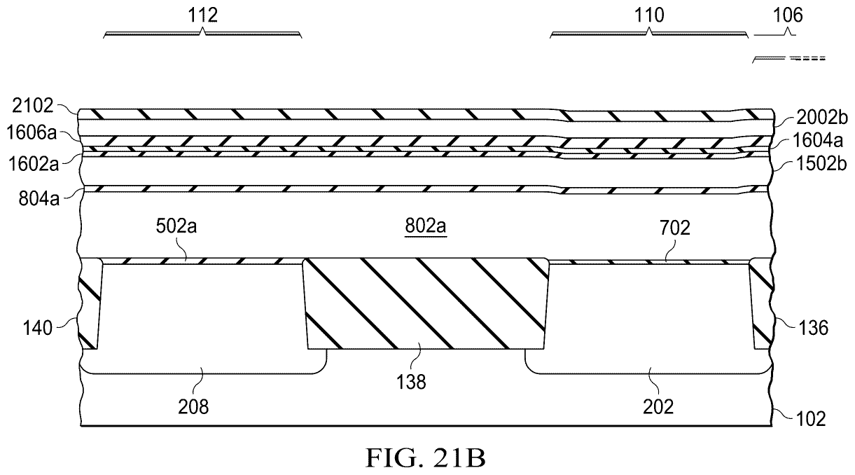

Referring to FIGS. 21A and 21B, an emitter dielectric cap layer 2102 is conformally formed over the emitter layer 2002. In some examples, the emitter dielectric cap layer 2102 is silicon oxide (e.g., a TEOS oxide) deposited by CVD, although other dielectric materials and/or other deposition processes may be used in other examples.

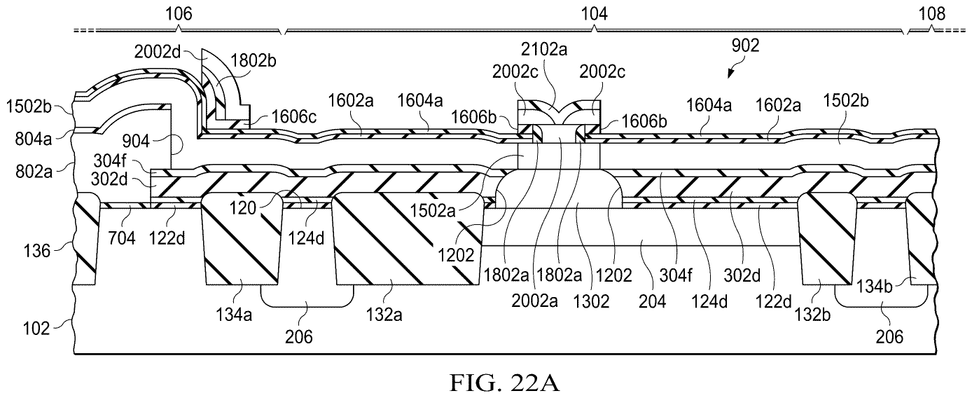

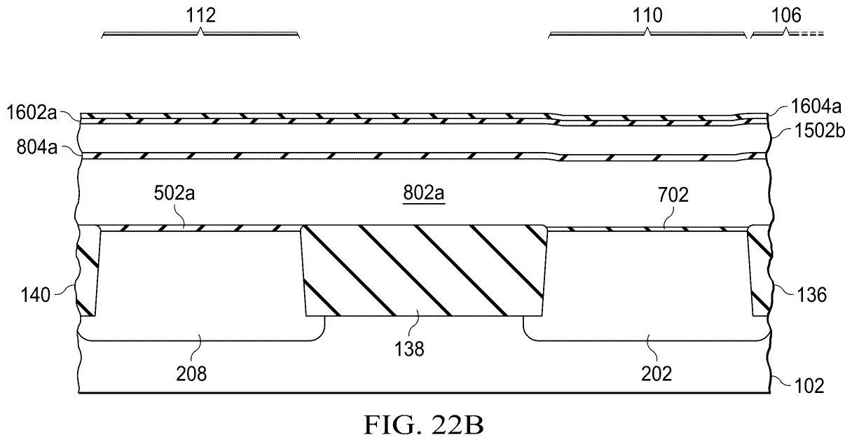

Referring to FIGS. 22A and 22B, the emitter dielectric cap layer 2102, polycrystalline emitter layer 2002b, and third dielectric spacer layer 1606a are patterned to form the emitter dielectric cap layer 2102a, polycrystalline emitter layer 2002c, and third dielectric spacer 1606b in the BJT region 104. In the illustrated example, the layers 2102, 2002b, 1606a are patterned using appropriate photolithography and etch (e.g., anisotropic etch, such as RIE) processes. Residual polycrystalline emitter layer 2002d and residual third dielectric spacer layer 1606c may remain at the sidewall 904 of the gate layer 802a in the first transition region 106 due to the etch process (e.g., anisotropic etch).

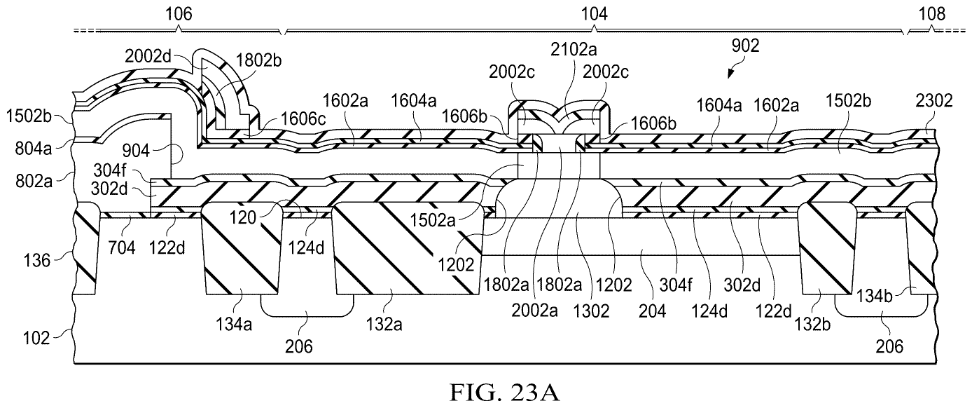

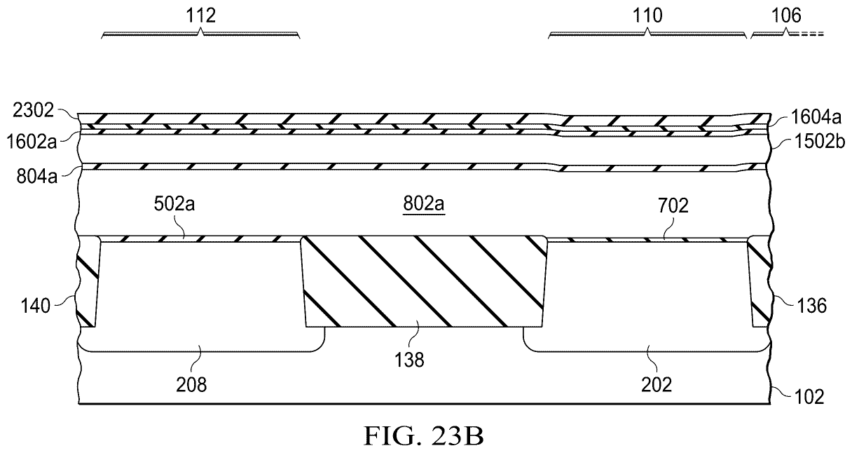

Referring to FIGS. 23A and 23B, an emitter dielectric protective spacer layer 2302 is conformally formed over the emitter dielectric cap layer 2102a and the second dielectric spacer layer 1604a and along sidewalls of the emitter dielectric cap layer 2102a, polycrystalline emitter layer 2002c, and third dielectric spacer 1606b in the BJT region 104. Additionally, the emitter dielectric protective spacer layer 2302 is conformally formed over the residual polycrystalline emitter layer 2002d and along sidewalls of the residual polycrystalline emitter layer 2002d and residual third dielectric spacer layer 1606c in the first transition region 106 and over the second dielectric spacer layer 1604a in the first transition region 106. The emitter dielectric protective spacer layer 2302 is formed over the second dielectric spacer layer 1604a in the pFET region 110 and nFET region 112. In some examples, the emitter dielectric protective spacer layer 2302 is silicon oxide (e.g., a TEOS oxide) deposited by CVD, although other dielectric materials and/or other deposition processes may be used in other examples.

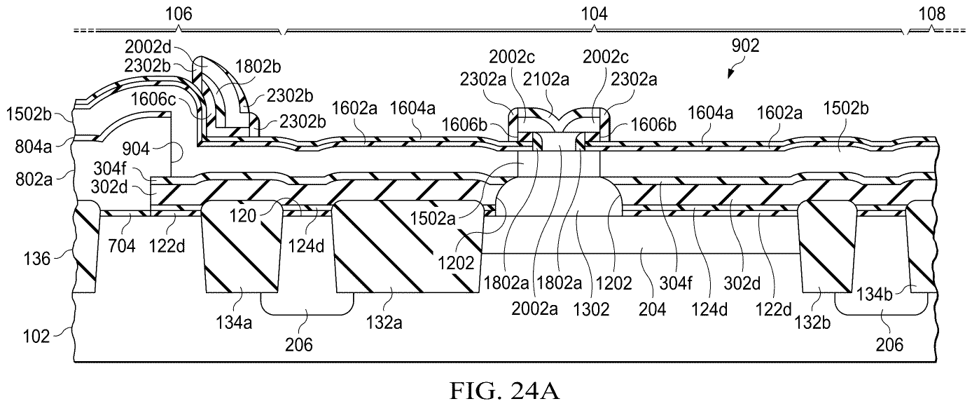

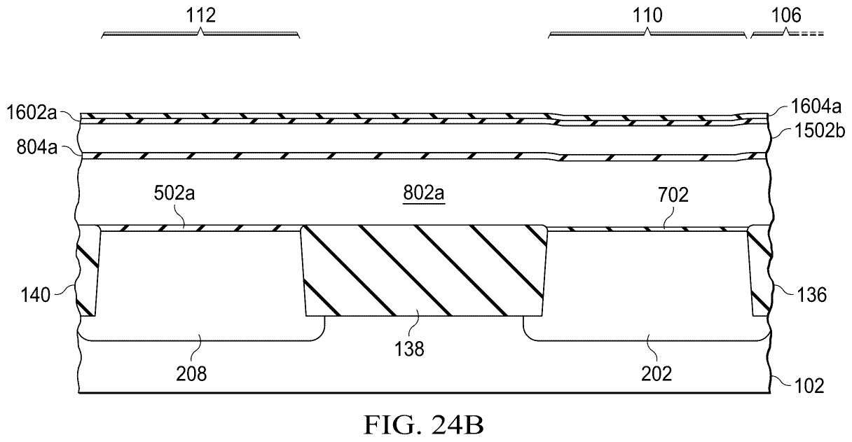

Referring to FIGS. 24A and 24B, the emitter dielectric protective spacer layer 2302 is anisotropically etched to form emitter dielectric protective spacers 2302a along sidewalls of the emitter dielectric cap layer 2102a, polycrystalline emitter layer 2002c, and third dielectric spacer 1606b. The emitter dielectric protective spacers 2302a protect sidewalls of the polycrystalline emitter layer 2002c. Additionally, residual dielectric spacers 2302b may remain on vertical surfaces, such as vertical surfaces of the residual polycrystalline emitter layer 2002d and residual third dielectric spacer layer 1606c in the first transition region 106. The anisotropic etch may be an RIE, for example.

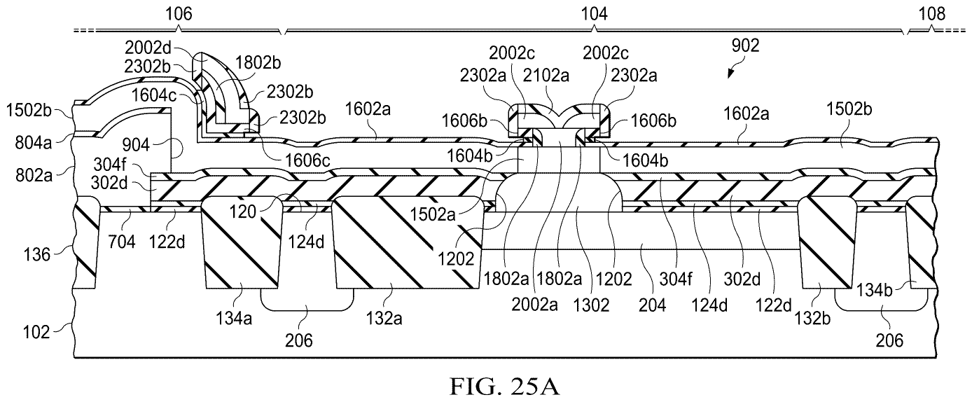

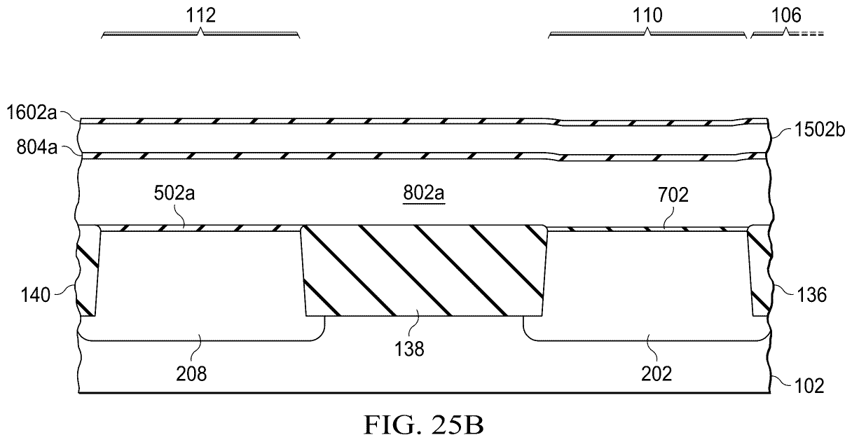

Referring to FIGS. 25A and 25B, the second dielectric spacer layer 1604a is etched. The etch removes exposed portions of the second dielectric spacer layer 1604a and undercuts the emitter dielectric protective spacers 2302a and third dielectric spacers 1606b laterally distal from the monocrystalline emitter layer 2002a, which results in second dielectric spacers 1604b under the third dielectric spacers 1606b. The etch may also undercut any of the residual dielectric spacer 2302b in the first transition region 106, which further forms residual second dielectric spacer layer 1604c. The etch may be a wet or dry etch selective to the material of the second dielectric spacer layer 1604a, which etch is also isotropic. For example, when the second dielectric spacer layer 1604a is silicon nitride, the etch process may be or include using phosphoric acid.

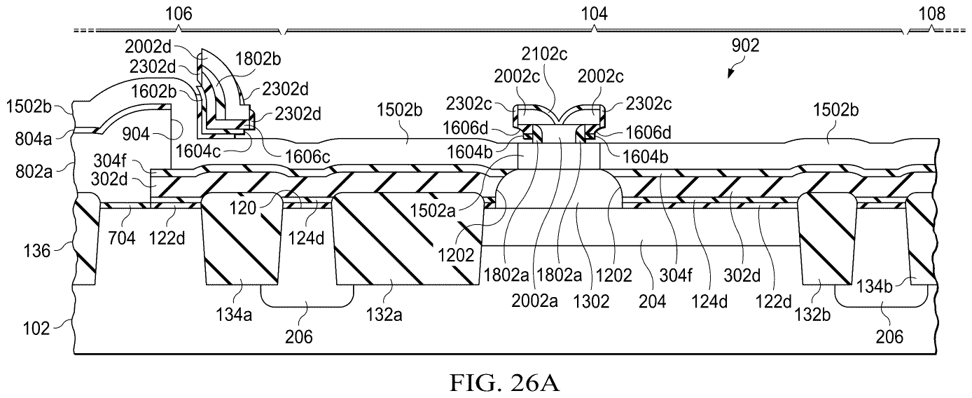

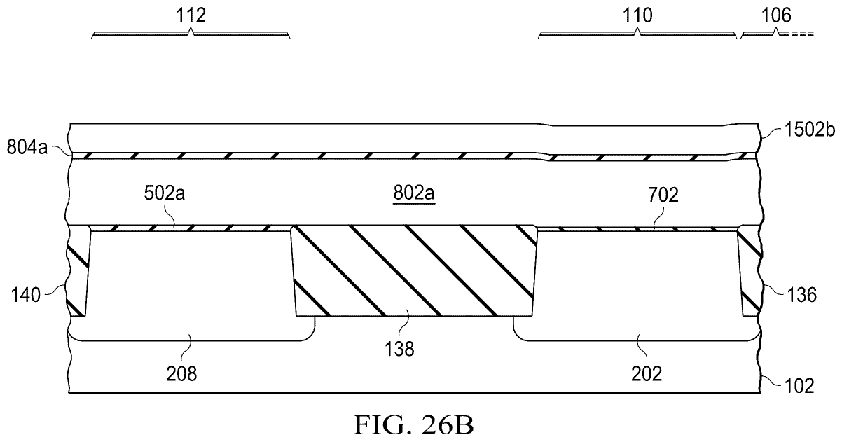

Referring to FIGS. 26A and 26B, the first dielectric spacer layer 1602a is etched. Etching the first dielectric spacer layer 1602a removes exposed portions of the first dielectric spacer layer 1602a, such as from the monocrystalline base layer 1502a. The etch may be a wet etch selective to the first dielectric spacer layer 1602a. A wet etch may remove the first dielectric spacer layer 1602a that underlies the emitter dielectric protective spacers 2302a and the second dielectric spacers 1604b. For example, when the first dielectric spacer layer 1602a is silicon oxide, the first dielectric spacer layer 1602a may be etched using a dilute hydrofluoric (dHF) acid etch. The removal of the first dielectric spacer layer 1602a opens (e.g., exposes) an area on the base layer 1502 near the monocrystalline emitter layer 2002a on which a raised base layer may be formed. Additionally, the wet etch may further etch the emitter dielectric cap layer 2102a, emitter dielectric protective spacers 2302a, and the third dielectric spacers 1606b when those layer and spacers are a same material as the first dielectric spacer layer 1602a, which reduces respective thicknesses of those layer and spacers and results in emitter dielectric cap layer 2102c, emitter dielectric protective spacers 2302c, and third dielectric spacers 1606d, such as illustrated. A residual first dielectric spacer layer 1602b remains under the residual second dielectric spacer layer 1604c in the first transition region 106. Additionally, in the first transition region 106, the wet etch may further etch the residual dielectric spacers 2302b when those spacers are a same material as the first dielectric spacer layer 1602a, which reduces the spacers resulting in residual dielectric spacers 2302d, such as illustrated.

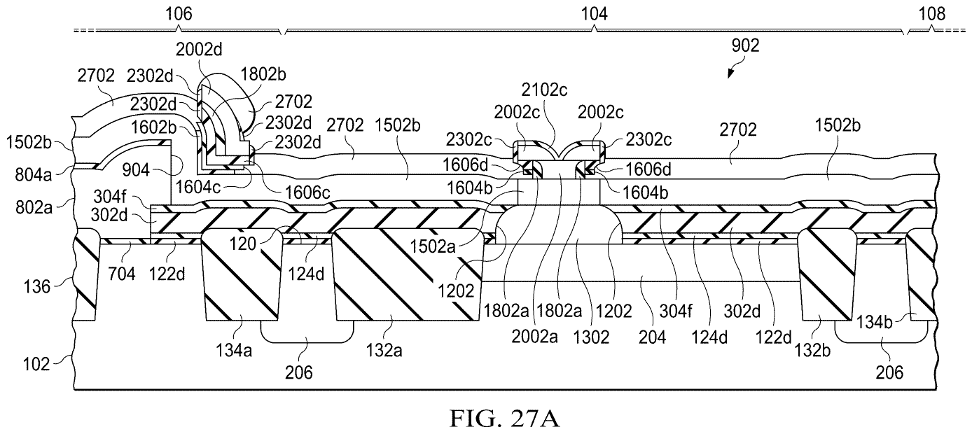

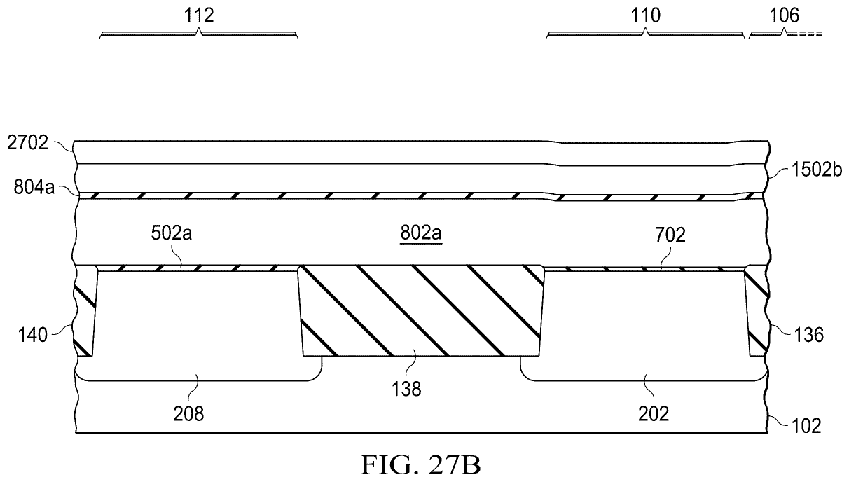

Referring to FIGS. 27A and 27B, a raised base layer 2702 is formed over the base layer 1502. The raised base layer 2702 includes at least a polycrystalline raised base layer on the polycrystalline base layer 1502b. The raised base layer 2702 may include a monocrystalline raised base layer. If the monocrystalline base layer 1502a is exposed by etching the first dielectric spacer layer 1602a, the raised base layer 2702 may include a monocrystalline portion on the monocrystalline base layer 1502a. In some examples, the raised base layer 2702 is or includes a semiconductor layer doped with a p-type dopant (e.g., a same dopant type as the base layer 1502). In some examples, the raised base layer 2702 is or includes silicon. In some examples, the raised base layer 2702 is doped with a p-type dopant with a concentration in a range from 1×10¹⁹ cm⁻³ to 1×10²¹ cm⁻³. The raised base layer 2702 may be epitaxially grown on the base layer 1502. The raised base layer 2702 may be epitaxially grown by a selective epitaxial growth process in some examples. The selective deposition of the raised base layer 2702 forms the raised base layer 2702 conformally on crystalline (e.g., polycrystalline and monocrystalline) surfaces, which include exposed portions of the base layer 1502 (e.g., the polycrystalline base layer 1502b). Further, the raised base layer 2702 may be in situ doped during the epitaxial growth process (e.g., the selective epitaxial growth process). The epitaxial growth process may be a CVD process, such as LPCVD, RPCVD, MOCVD, or the like. Other materials, dopant type, dopant concentration, and/or deposition process may be implemented.

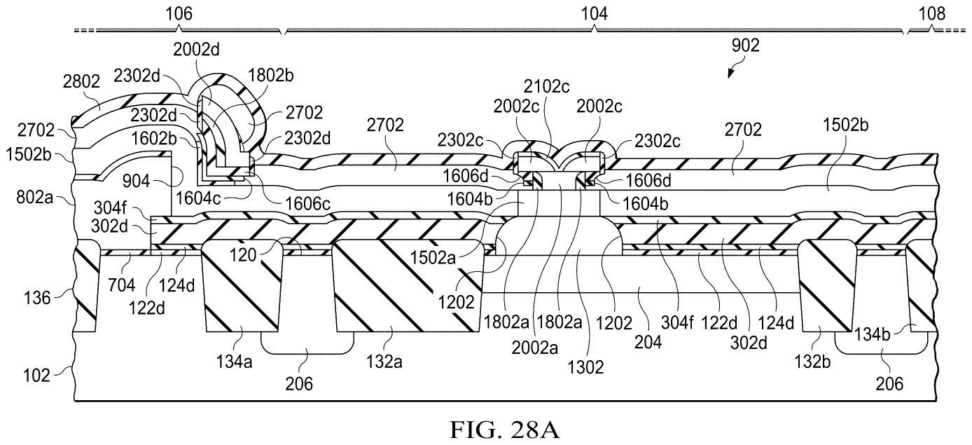

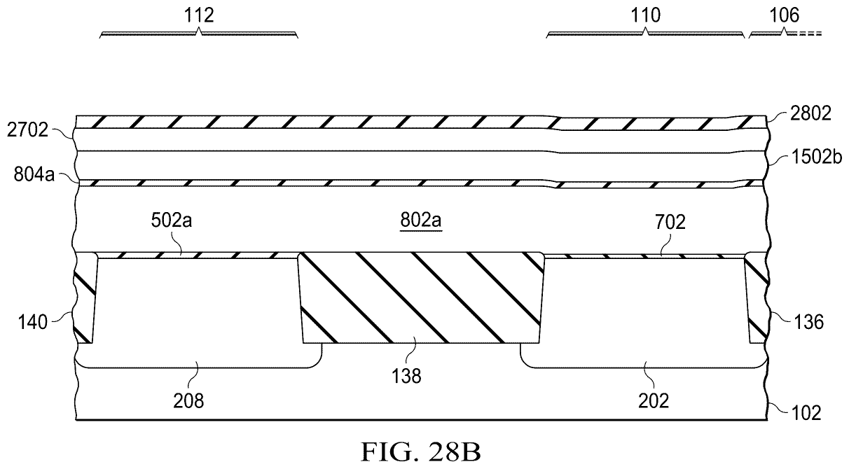

Referring to FIGS. 28A and 28B, a dielectric protective layer 2802 is conformally formed over and along the emitter dielectric cap layer 2102c, the emitter dielectric protective spacers 2302c, and the raised base layer 2702 in the BJT region 104. The dielectric protective layer 2802 is further conformally formed over and along the raised base layer 2702 and the residual dielectric spacers 2302d in the first transition region 106 and over the raised base layer 2702 in the pFET region 110 and nFET region 112. In some examples, the dielectric protective layer 2802 is silicon oxide (e.g., a TEOS oxide) deposited by CVD, although other dielectric materials and/or other deposition processes may be used in other examples.

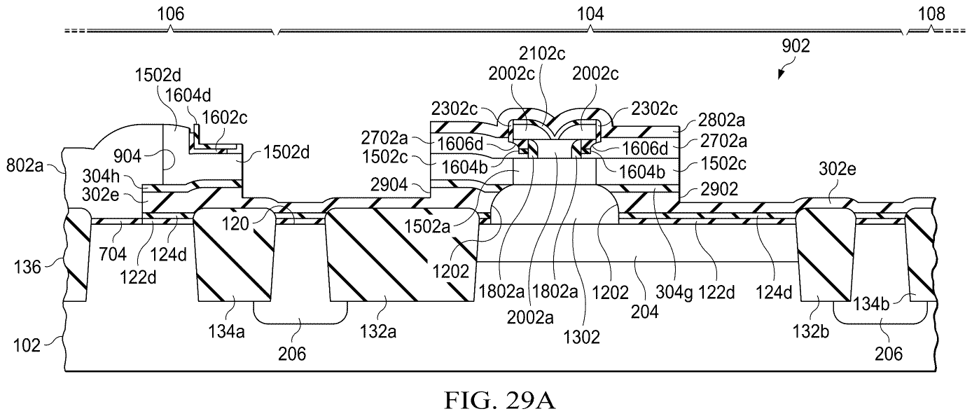

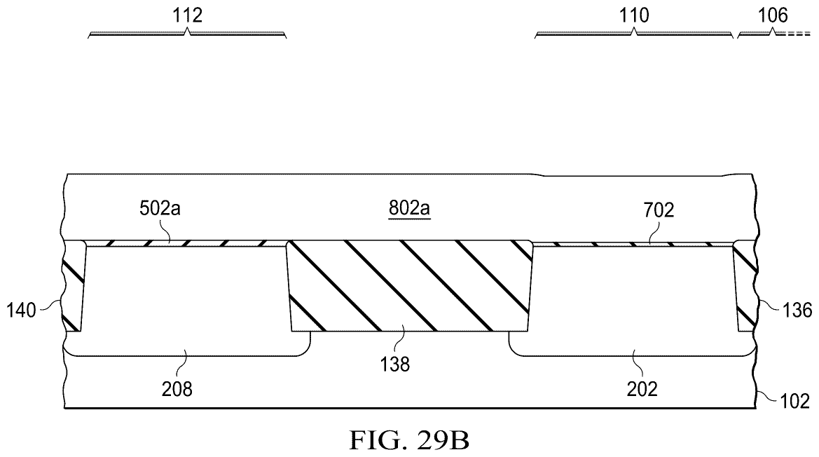

Referring to FIGS. 29A and 29B, the dielectric protective layer 2802, the raised base layer 2702, the base layer 1502 (e.g., the polycrystalline base layer 1502b), and the fourth pedestal oxide sub-layer 304f are patterned in the BJT region 104. The dielectric protective layer 2802, raised base layer 2702, the polycrystalline base layer 1502b, and the fourth pedestal oxide sub-layer 304f are patterned to remain as the dielectric protective layer 2802a, the raised base layer 2702a, the polycrystalline base layer 1502c, and the fourth pedestal oxide sub-layer 304g, respectively, in the BJT region 104. Further, the third pedestal oxide sub-layer 302d is thinned in areas where the dielectric protective layer 2802, the raised base layer 2702, the polycrystalline base layer 1502b, and the fourth pedestal oxide sub-layer 304f are removed and results in the third pedestal oxide sub-layer 302e. Patterning the fourth pedestal oxide sub-layer 304f and thinning the third pedestal oxide sub-layer 302d results in sidewalls 2902, 2904 of the fourth and third pedestal oxide sub-layers 304g, 302e that align with respective sidewalls of the polycrystalline base layer 1502c and, further, the raised base layer 2702a. The layers 2802, 2702, 1502b, 304f, 302d may be patterned or thinned using appropriate photolithography and etch (e.g., RIE) processes.

As illustrated, etching the dielectric protective layer 2802, the raised base layer 2702, and the polycrystalline base layer 1502b may remove the dielectric protective layer 2802, the residual dielectric spacers 2302d, the raised base layer 2702, and the residual polycrystalline emitter layer 2002d from the first transition region 106. Thereafter, etching the fourth and third pedestal oxide sub-layers 304f may remove any remaining residual dielectric spacers 2302d, the residual dielectric spacers 1802b, the residual third dielectric spacer layer 1606c, and the dielectric protective layer 804a in the first transition region 106. Etching the fourth pedestal oxide sub-layer 304f results in a residual fourth pedestal oxide sub-layer 304h remaining in the first transition region 106. A residual polycrystalline base layer 1502d remains in the first transition region 106 along the sidewall 904 of the gate layer 802a and over the residual oxide layer 304h. The various etches may also reduce the residual dielectric spacer layers 1604c, 1602b such that residual dielectric spacer layers 1604d, 1602c remain over the residual polycrystalline base layer 1502d. Further, the various etches remove the dielectric protective layer 2802, the raised base layer 2702, the polycrystalline base layer 1502b, and the dielectric protective layer 804a from the pFET region 110 and the nFET region 112.

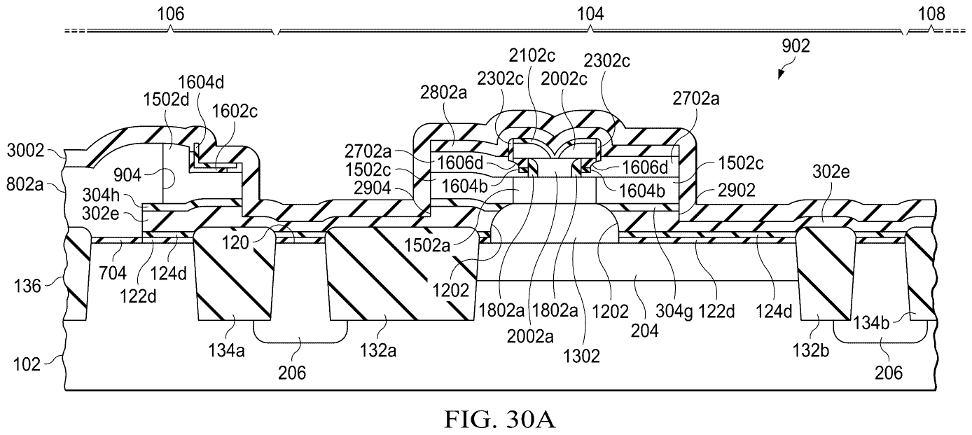

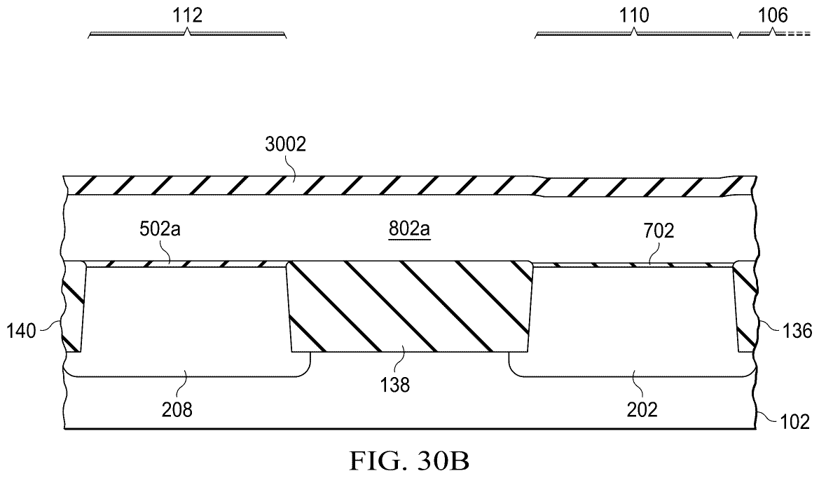

Referring to FIGS. 30A and 30B, a hardmask layer 3002 is conformally formed over the semiconductor substrate 102. More specifically, the hardmask layer 3002 is conformally formed over the third pedestal oxide sub-layer 302e and the dielectric protective layer 2802a and along sidewalls of the dielectric protective layer 2802a, the raised base layer 2702a, the polycrystalline base layer 1502c, and the fourth and third pedestal oxide sub-layers 304g, 302e in the BJT region 104. The hardmask layer 3002 is conformally formed over the gate layer 802a in the first transition region 106, the pFET region 110, and the nFET region 112 and is conformally formed over and along respective sidewalls of the residual fourth pedestal oxide sub-layer 304h, residual polycrystalline base layer 1502d, and the residual dielectric spacer layers 1602c, 1604d in the first transition region 106. In some examples, the hardmask layer 3002 is or includes silicon nitride deposited by CVD, although other hardmask (e.g., dielectric) materials and/or other deposition processes may be used in other examples.

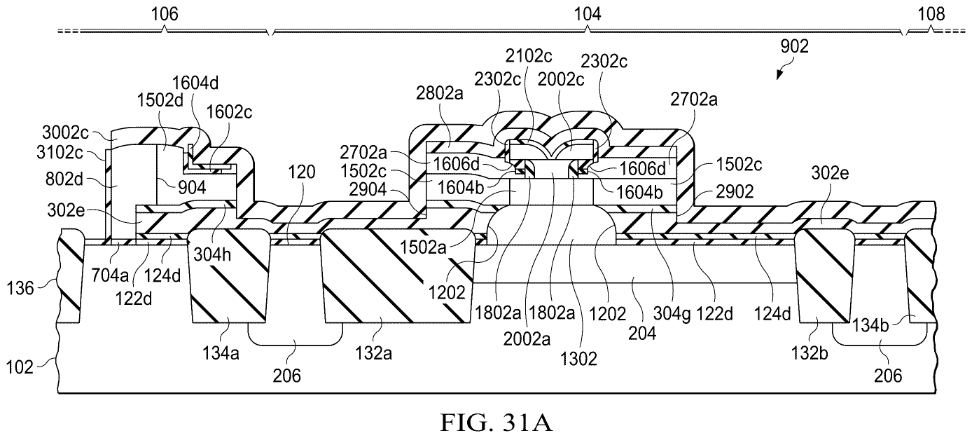

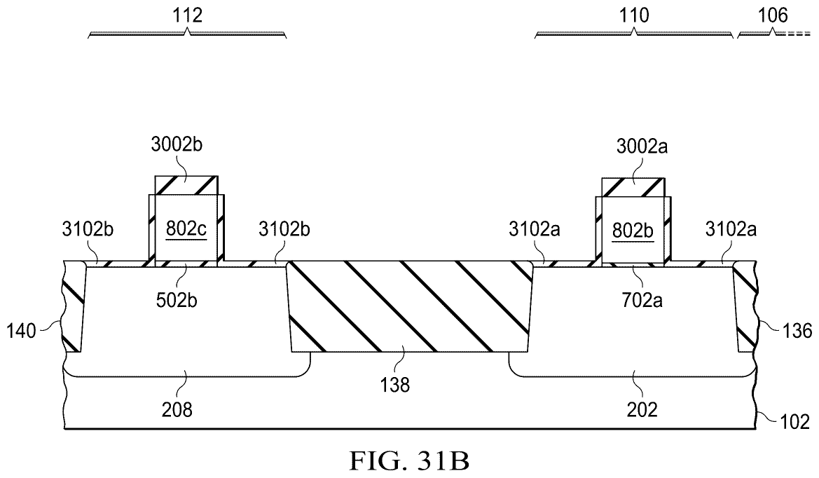

Referring to FIGS. 31A and 31B, the hardmask layer 3002, the gate layer 802a, and the gate oxide layers 702, 502a are patterned into hardmask layers 3002a, 3002b, gate electrodes 802b, 802c, and gate oxide layers 702a, 502b in the pFET region 110 and nFET region 112, respectively. The gate electrode 802b is over (e.g., on) the gate oxide layer 702a in the pFET region 110, and the gate electrode 802c is over (e.g., on) the gate oxide layer 502b in the nFET region 112. The hardmask layers 3002a, 3002b remain over (e.g., on) the gate electrodes 802b, 802c, respectively. The hardmask layer 3002, the gate layer 802a, and the gate oxide layers 702, 502a may be patterned using appropriate photolithography and etch (e.g., RIE) processes. Patterning the hardmask layer 3002 results in hardmask layer 3002c remaining in the BJT region and transition regions 108, 106. A residual gate layer 802d (with the sidewall 904) remains in the first transition region 106 along sidewalls of and over, among others, the residual fourth pedestal oxide sub-layer 304h and the third pedestal oxide sub-layer 302c.

Reoxidation layers 3102a, 3102b are formed along sidewalls of the gate electrodes 802b, 802c and exposed portions of the upper surface 120 of the semiconductor substrate 102. The reoxidation layer 3102a is along sidewalls of the gate electrode 802b and exposed portions of the upper surface 120 in the pFET region 110, and the reoxidation layer 3102b is along sidewalls of the gate electrode 802c and exposed portions of the upper surface 120 in the nFET region 112. The reoxidation layers 3102a, 3102b may be formed by an oxidation process, such as by ISSG oxidation. The formation of the reoxidation layers 3102a, 3102b may remove damage on the sidewalls of the gate electrodes 802b, 802c and/or the upper surface 120 formed by the etch process that patterns the gate electrodes 802b, 802c, which damage may be plasma-induced. The formation of the reoxidation layers 3102a, 3102b may reduce gate-induced drain leakage current in the FETs (that include the gate electrodes 802b, 802c) that are to be formed. Additionally, the oxidation process the forms the reoxidation layers 3102a, 3102b, in some examples, forms a residual reoxidation layer 3102c on an exposed portion of the upper surface 120 and a sidewall of the residual gate layer 802d (opposite from the sidewall 904) in the first transition region 106.

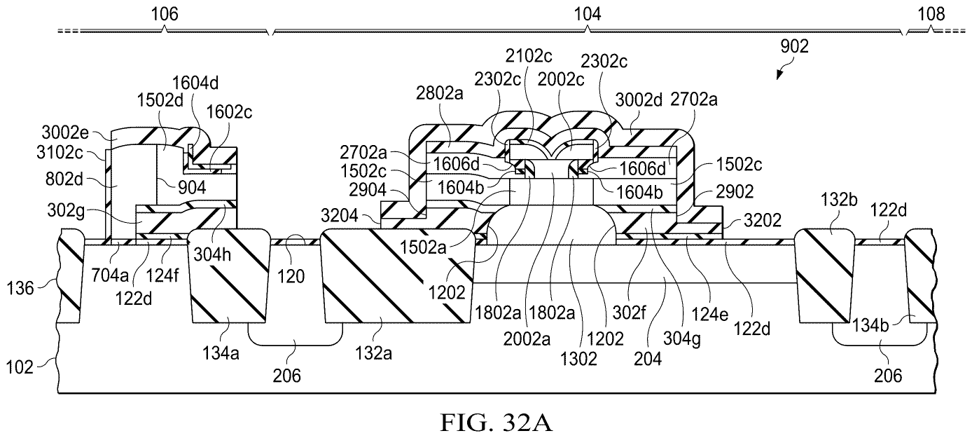

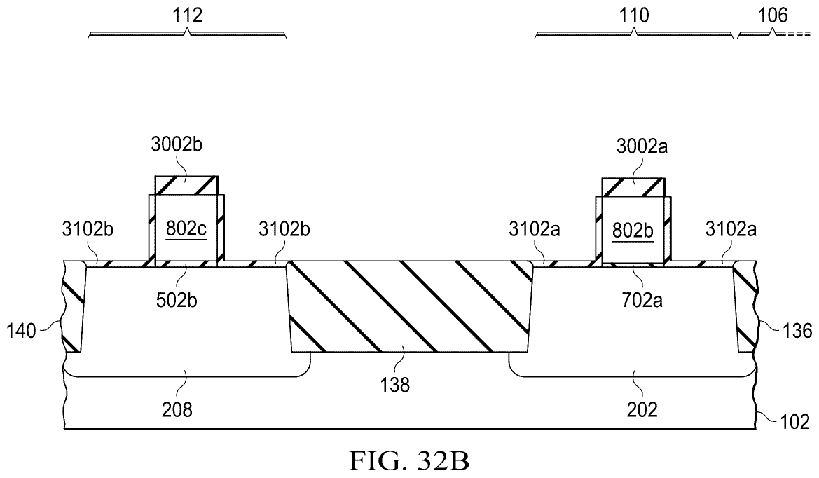

Referring to FIGS. 32A and 32B, the hardmask layer 3002c and the third and second pedestal oxide sub-layers 302e, 124d are patterned into hardmask layers 3002d, 3002c, third pedestal oxide sub-layer 302f, residual third pedestal oxide sub-layer 302g, second pedestal oxide sub-layer 124c, and residual second pedestal oxide sub-layer 124f. The hardmask layer 3002d, third pedestal oxide sub-layer 302f, and second pedestal oxide sub-layer 124e are in the BJT region 104. Specifically, the hardmask layer 3002d is over the dielectric protective layer 2802a and the third pedestal oxide sub-layer 302f, along sidewalls of the dielectric protective layer 2802a, the raised base layer 2702a and the polycrystalline base layer 1502c, and along the sidewalls 2902, 2904 of the fourth and third pedestal oxide sub-layers 304g, 302f. The hardmask layer 3002d extends over the third pedestal oxide sub-layer 302f laterally away from the polycrystalline base layer 1502c and from the sidewalls 2902, 2904 of the fourth and third pedestal oxide sub-layers 304g, 302f. The third and second pedestal oxide sub-layers 302g, 124c are laterally coextensive with the hardmask layer 3002d. Patterning the third and second pedestal oxide sub-layers 302e 124d forms the third and second pedestal oxide sub-layers 302f, 124c with a sidewall 3202 and forms the third pedestal oxide sub-layer 302f with a sidewall 3204. The sidewalls 3202, 3204 are laterally away from respective sidewalls 2902, 2904 of the fourth and third pedestal oxide sub-layers 304g, 302c. The sidewall 3202 of the third and second pedestal oxide sub-layer 302e, 124e is over the upper surface 120 of the semiconductor substrate 102 and the n-type doped sub-collector diffusion region 204. The sidewall 3204 of the third pedestal oxide sub-layer 302e is over the first portion 132a of the isolation structure 132. Portions of the hardmask layer 3002c and the third and second pedestal oxide sub-layers 302e, 124d are removed from over at least a portion of the n-type doped sub-collector diffusion region 204 and the p-type doped well 206. The hardmask layer 3002c and the third and second pedestal oxide sub-layers 302e, 124d may be patterned using appropriate photolithography and etch (e.g., RIE) processes. Although the patterning is illustrated and described as being through the second pedestal oxide sub-layer 124d, the patterning may be into (e.g., not through) the second pedestal oxide sub-layer 124d or may be through the second pedestal oxide sub-layer 124d and into the first pedestal oxide sub-layer 122d.

The hardmask layer 3002e, residual third pedestal oxide sub-layer 302g, and residual second pedestal oxide sub-layer 124f are in the first transition region 106. The residual third pedestal oxide sub-layer 302g is over the residual second pedestal oxide sub-layer 124f and the first portion 134a of the isolation structure 134 and is under the residual fourth pedestal oxide sub-layer 304h.

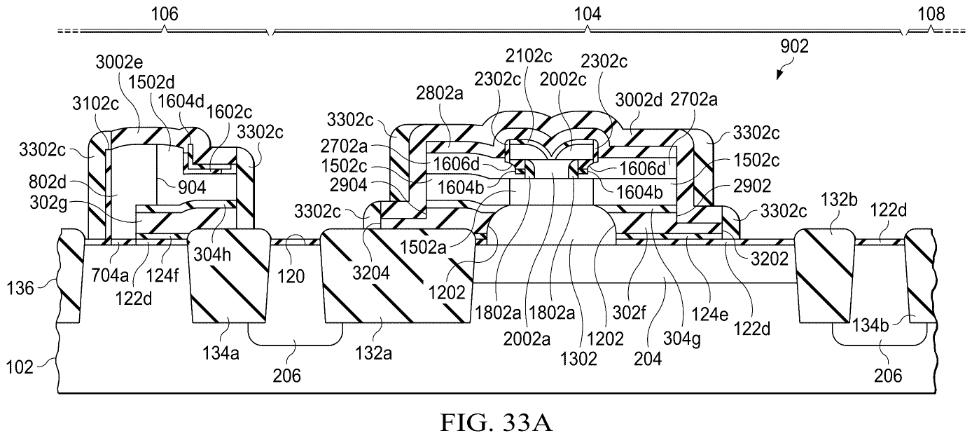

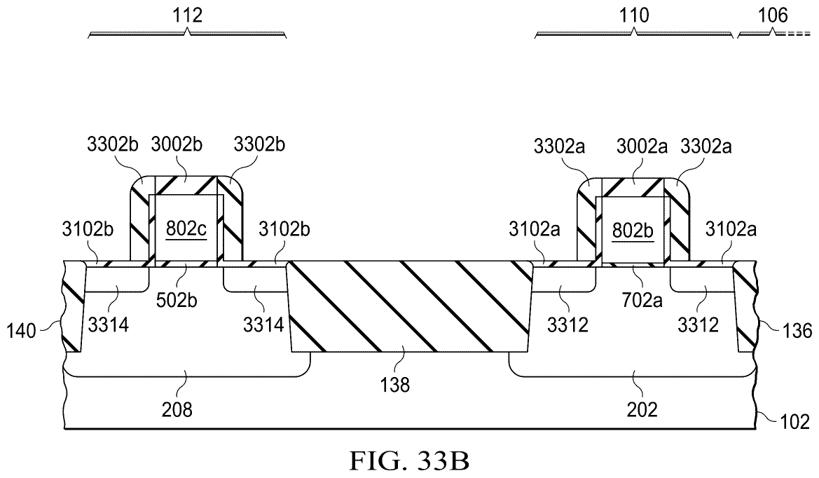

Referring to FIGS. 33A and 33B, first gate dielectric spacers 3302a, 3302b are formed along the sidewalls of the gate electrodes 802b, 802c (e.g., on the reoxidation layers 3102a, 3102b). The first gate dielectric spacers 3302a, 3302b may be formed by depositing a layer of the material of the first gate dielectric spacers 3302a, 3302b conformally over the semiconductor substrate 102 and anisotropically etching (e.g., by RIE) the layer such that the first gate dielectric spacers 3302a, 3302b remain. The material of the first gate dielectric spacers 3302a, 3302b may be any appropriate dielectric material, such as silicon nitride, silicon oxynitride, silicon carbon nitride, the like, or a combination thereof. The layer may be deposited by CVD, PECVD, ALD, or the like. The formation of the first gate dielectric spacers 3302a, 3302b may further form residual dielectric spacers 3302c on vertical surfaces in the BJT region 104 and first transition region 106, such as vertical surfaces of the hardmask layers 3002d, 3002c, etc.

P-type lightly doped drain regions (LDDs) 3312 and n-type LDDs 3314 are formed in the semiconductor substrate 102 in the pFET region 110 and the nFET region 112, respectively. The p-type LDDs 3312 and the n-type LDDs 3314 may be formed before forming the first gate dielectric spacers 3302a, 3302b in some examples and may be formed after forming the first gate dielectric spacers 3302a, 3302b in some examples. The p-type LDDs 3312 are in the semiconductor substrate 102 on laterally opposing sides of the gate electrode 802b, and the n-type LDDs 3314 are in the semiconductor substrate 102 on laterally opposing sides of the gate electrode 802c. The p-type LDDs 3312 may be formed by masking (e.g., by a photoresist using photolithography) the BJT region 104, transition regions 106, 108, and nFET region 112 and implanting a p-type dopant into the semiconductor substrate 102 in the pFET region 110. The n-type LDDs 3314 may be formed by masking (e.g., by a photoresist using photolithography) the BJT region 104, transition regions 106, 108, and pFET region 110 and implanting an n-type dopant into the semiconductor substrate 102 in the nFET region 112. A concentration of the p-type dopant of the p-type LDDs 3312 is greater than the concentration of the n-type dopant of the n-type doped well 202, and a concentration of the n-type dopant of the n-type LDDs 3314 is greater than the concentration of the p-type dopant of the p-type doped well 208. In some examples, the p-type LDDs 3312 are doped with a p-type dopant with a concentration in a range from 1×10¹⁹ cm⁻³ to 1×10²¹ cm⁻³, and the n-type LDDs 3314 are doped with an n-type dopant with a concentration in a range from 1×10¹⁹ cm⁻³ to 1×10²¹ cm⁻³. Other doping concentrations may be implemented. After performing implantation(s) to form the p-type LDDs 3312 and the n-type LDDs 3314, an activation anneal may be performed.

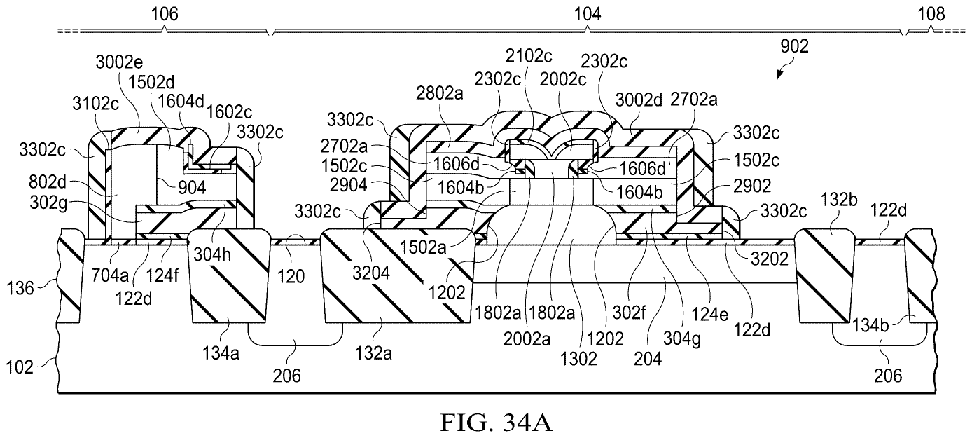

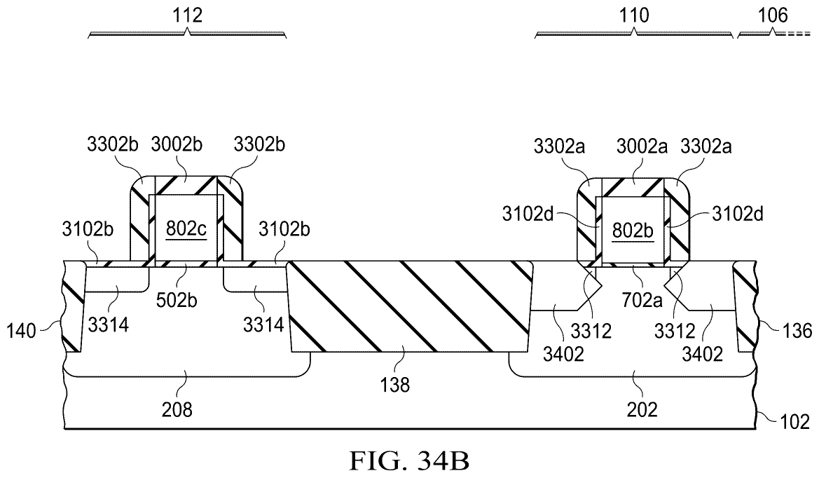

Referring to FIGS. 34A and 34B, embedded stressors 3402 are formed in the semiconductor substrate 102 in the pFET region 110. To form the embedded stressors 3402, respective recesses are formed in the semiconductor substrate 102. To form the recesses, a conformal hardmask layer (not illustrated) is formed over the semiconductor substrate 102 in the BJT region 104, transition regions 106, 108, and nFET region 112. The conformal hardmask layer may be or include silicon nitride, silicon oxynitride, the like, or a combination thereof. The conformal hardmask layer may be formed by conformally depositing and patterning the conformal hardmask layer. The conformal hardmask layer may be deposited by CVD, PECVD, ALD, or the like. The conformal hardmask layer may be patterned using photolithography and etching (e.g., RIE) processes. Then, stressor recesses are formed in the semiconductor substrate 102 in the pFET region 110. The stressor recesses are etched in the semiconductor substrate 102 where the embedded stressors are to be formed, which may pattern the reoxidation layers 3102a into reoxidation layers 3102d underlying respective first gate dielectric spacers 3302a. The stressor recesses may be formed using any appropriate etch process, which may be a wet or dry etch process. The etch process may be anisotropic and selective to (e.g., etching preferentially) a crystalline plane of the semiconductor substrate 102. The embedded stressors 3402 are then formed in the stressor recesses. The embedded stressors 3402 may be formed using a selective epitaxial growth process. The embedded stressors 3402 may be formed using MOCVD, molecular beam epitaxy (MBE), LPCVD, or another epitaxy process. In some examples, the embedded stressors 3402 are a semiconductor material that causes a compressive stress in the channel region in the semiconductor substrate 102 under the gate electrode 802b. For example, when the semiconductor substrate 102 is silicon, the embedded stressors 3402 may be or include silicon germanium.

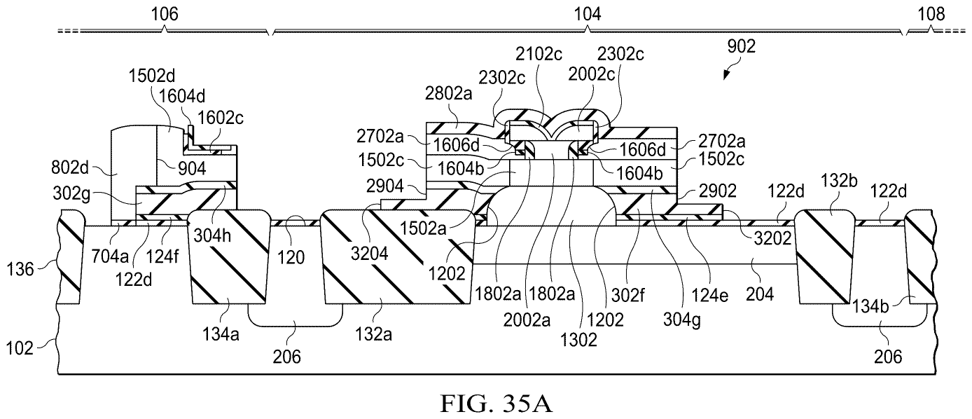

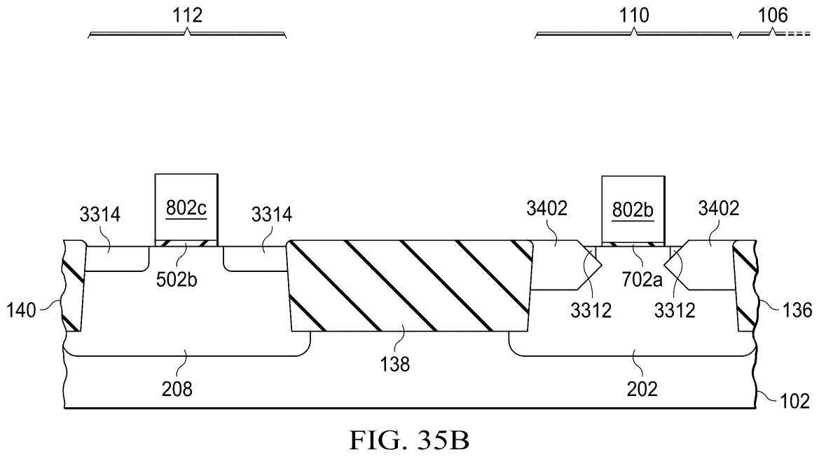

Referring to FIGS. 35A and 35B, the conformal hardmask layer for forming the embedded stressors 3402, the dielectric spacers 3302a, 3302b, 3302c, and the hardmask layers 3002a, 3002b, 3002d, 3002e are removed. These layers and spacers may be removed by an etch process selective to the material of the respective layers and spacers, which may be wet or dry etch processes and may be isotropic. As an example, when the conformal hardmask layer, the dielectric spacers 3302a, 3302b, 3302c, and the hardmask layers 3002a, 3002b, 3002d, 3002e are silicon nitride, a wet etch process including phosphoric acid may be implemented. Further, after removing the dielectric spacers 3302a, 3302b, 3302c, and the hardmask layers 3002a, 3002b, 3002d, 3002e, a cleaning process may remove, as illustrated, the reoxidation layers 3102b, 3102c, 3102d. Although not illustrated, the cleaning process may thin the first pedestal oxide sub-layer 122d.

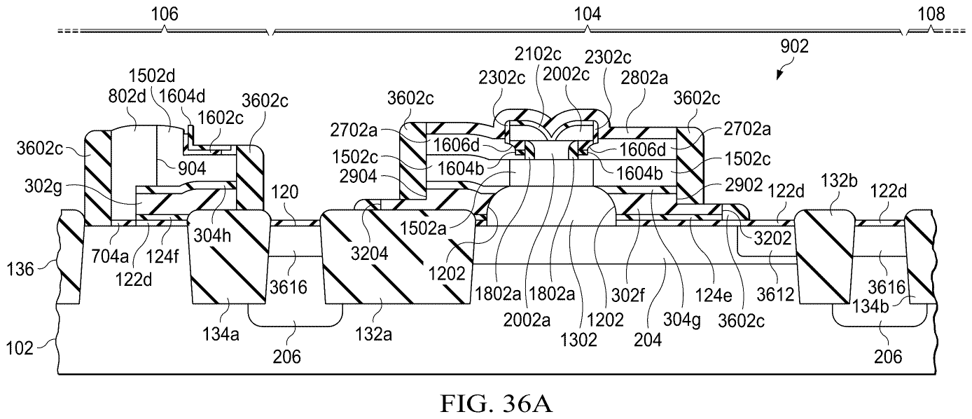

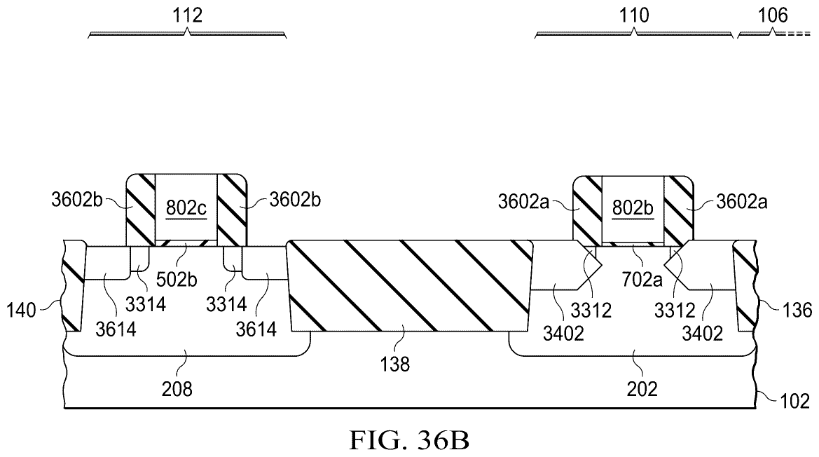

Referring to FIGS. 36A and 36B, second gate dielectric spacers 3602a, 3602b are formed along the sidewalls of the gate electrodes 802b, 802c, respectively. The second gate dielectric spacers 3602a, 3602b may be formed by depositing a layer of the material of the second gate dielectric spacers 3602a, 3602b conformally over the semiconductor substrate 102 and anisotropically etching (e.g., by RIE) the layer such that the second gate dielectric spacers 3602a, 3602b remain. The material of the second gate dielectric spacers 3602a, 3602b may be any appropriate dielectric material, such as silicon nitride, silicon oxynitride, silicon carbon nitride, the like, or a combination thereof. The layer may be deposited by CVD, PECVD, ALD, or the like. The formation of the second gate dielectric spacers 3602a, 3602b may further form residual dielectric spacers (e.g., residual dielectric spacers 3602c) on sidewalls of components in the BJT region 104 and/or the first transition region 106.

A stress memorization technique may be implemented, such as in the nFET region 112. A stressor dielectric layer is formed over the semiconductor substrate 102, gate electrode 802c, and second gate dielectric spacers 3602b in the nFET region 112. The stressor dielectric layer may be or include silicon nitride, the like, or a combination thereof. The stressor dielectric layer may be formed by conformally depositing and patterning the stressor dielectric layer. The stressor dielectric layer may be deposited by CVD, PECVD, ALD, or the like. The stressor dielectric layer may be patterned using photolithography and etching processes. An anneal process is performed with the stressor dielectric layer in the nFET region 112. The anneal process permits the lattice structure of the semiconductor substrate 102 to conform due to the stress induced by the stressor dielectric layer. After the anneal process, the stressor dielectric layer is removed. The stressor dielectric layer may be removed by an etch process selective to the material of the stressor dielectric layer, which may be a wet or dry etch process.

An n-type collector contact region 3612, n-type source/drain (NSD) regions 3614, p-type source/drain (PSD) regions, and a p-type guardring contact region 3616 are formed in the semiconductor substrate 102. The n-type collector contact region 3612 is formed in the BJT region 104 in the n-type doped sub-collector diffusion region 204 in the semiconductor substrate 102. The n-type collector contact region 3612 is laterally between the sidewall 3202 of the third and second pedestal oxide sub-layers 302f, 124e and the second portion 132b of the isolation structure 132. The NSD regions 3614 are formed in the nFET region 112 in the p-type doped well 208 in the semiconductor substrate 102. The NSD regions 3614 are on opposing lateral sides of the gate electrode 802c with the n-type LDDs 3314 therebetween. The PSD regions are formed in the pFET region 110 and may be formed in the embedded stressors 3402 and/or may further extend below the embedded stressors 3402 into the n-type doped well 202 in the semiconductor substrate 102. The PSD regions are on opposing lateral sides of the gate electrode 802b with the p-type LDDs 3312 therebetween. The p-type guardring contact region 3616 is formed in the BJT region 104 in the p-type doped well 206 in the semiconductor substrate 102. The p-type guardring contact region 3616 is laterally between the isolation structures 132, 134.

An implantation is performed to form the n-type collector contact region 3612 and the NSD regions 3614. The n-type collector contact region 3612 and the NSD regions 3614 may be formed by masking (e.g., by a photoresist using photolithography) the pFET region 110 and the base layer 1502, raised base layer 2702a, and emitter layer 2002 in the BJT region 104 and implanting an n-type dopant into the semiconductor substrate 102 in the nFET region 112 and exposed portion of the BJT region 104. An implantation is performed to form the PSD regions and the p-type guardring contact region 3616. The PSD regions and the p-type guardring contact region 3616 may be formed by masking (e.g., by a photoresist using photolithography) the BJT region 104, except the p-type doped well 206, and the nFET region 112 and implanting a p-type dopant into the semiconductor substrate 102 in the pFET region 110 and in the p-type doped well 206. Simultaneously with implanting the PSD regions and the p-type guardring contact region 3616, the raised base layer 2702a and/or base layer 1502 may be implanted. An area of the raised base layer 2702a may be exposed by the mask during the implantation of the PSD regions and the p-type guardring contact region 3616 to also implant p-type dopant into the raised base layer 2702a and/or base layer 1502.

A concentration of the n-type dopant of the n-type collector contact region 3612 is greater than the concentration of the n-type dopant of the n-type doped sub-collector diffusion region 204. A concentration of the n-type dopant of the NSD regions 3614 is greater than the concentration of the n-type dopant of the n-type LDDs 3314 and the concentration of the p-type dopant of the p-type doped well 208. A concentration of the p-type dopant of the PSD regions is greater than the concentration of the p-type dopant of the p-type LDDs 3312 and the concentration of the n-type dopant of the n-type doped well 202. A concentration of the p-type guardring contact region 3616 is greater than the concentration of the p-type dopant of the p-type doped well 206. In some examples, the n-type collector contact region 3612 and the NSD regions 3614 are doped with an n-type dopant with a concentration in a range from 1×10²⁰ cm⁻³ to 1×10²¹ cm⁻³, and the PSD regions and the p-type guardring contact region 3616 are doped with a p-type dopant with a concentration in a range from 1×10²⁰ cm⁻³ to 1×10²¹ cm⁻³. Other doping concentrations may be implemented. After performing the implantations to form the n-type collector contact region 3612, NSD regions 3614, PSD regions, and p-type guardring contact region 3616, an activation anneal may be performed.

Referring to FIGS. 37A and 37B, metal-semiconductor compound 3702, 3704, 3706, 3708, 3710, 3712, 3714, 3716, 3718 are formed. The metal-semiconductor compound 3702 is on the emitter layer 2002 (e.g., the polycrystalline emitter layer 2002c and/or monocrystalline emitter layer 2002a). The metal-semiconductor compound 3704 is on the raised base layer 2702a. The metal-semiconductor compound 3706 is on the upper surface 120 of the semiconductor substrate 102 at the n-type collector contact region 3612. The metal-semiconductor compound 3708 is on the upper surface 120 of the semiconductor substrate 102 at the p-type guardring contact region 3616. The metal-semiconductor compound 3710 is on any exposed upper surface of a semiconductor material in the first transition region 106, such as the upper surface 120 of the semiconductor substrate 102 and upper surfaces of the residual gate layer 802d and residual polycrystalline base layer 1502d. The metal-semiconductor compound 3712 are on the embedded stressors 3402. The metal-semiconductor compound 3714 are on the NSD regions 3614 in the semiconductor substrate 102. The metal-semiconductor compound 3716, 3718 are on the gate electrodes 802b, 802c, respectively. The metal-semiconductor compound 3702-3718 may be a silicide (e.g., NiSix, TiSix, CoSix, PtSix), a germanicide, or the like.

To form the metal-semiconductor compound 3702-3718, any remaining dielectric material on surfaces on which the metal-semiconductor compound 3702-3718 are to be formed is removed. For example, if any of the dielectric protective layer 2802a, the emitter dielectric cap layer 2102c, and exposed portions of the first pedestal oxide sub-layer 122d remain after forming the second gate dielectric spacers 3602a, 3602b, those layers, or exposed portions thereof, may be removed by an etch and/or cleaning process. For example, when the layers 2802a, 2102c, 122d are silicon oxide, dilute hydrofluoric (dHF) acid may be used. The portions of the first pedestal oxide sub-layer 122d not underlying the second pedestal oxide sub-layers 124c, 124f are removed, which patterns the first pedestal oxide sub-layers 122e, 122f under the second pedestal oxide sub-layers 124e, 124f, respectively. Other layers and/or spacers may be reduced by the etch and/or cleaning process. For example, the emitter dielectric protective spacers 2302c may be reduced, such as to emitter dielectric protective spacers 2302e, and exposed portions of the third pedestal oxide sub-layer 302f, are thinned to form the third pedestal oxide sub-layer 302h. More specifically, the exposed portions of the third pedestal oxide sub-layer 302f between the sidewalls 2902, 3202 and between the sidewalls 2904, 3204 are thinned.

The metal-semiconductor compound 3702-3718 may then be formed by depositing a metal (e.g., Ni, Ti, Co, Pt) over the semiconductor substrate 102, such as by physical vapor deposition (PVD), CVD, or the like. The metal is reacted with a semiconductor material, such as the semiconductor material of the emitter layer 2002 (e.g., polycrystalline emitter layer 2002c and/or monocrystalline emitter layer 2002a), the semiconductor material of the raised base layer 2702a, the semiconductor material of the semiconductor substrate 102, the semiconductor material of the embedded stressors 3402, and the semiconductor material (e.g., silicon, such as polysilicon) of the gate electrodes 802b, 802c. An anneal process may be used to cause the metal to react with a semiconductor material.

After forming the metal-semiconductor compound 3702-3718, in some examples, the second gate dielectric spacers 3602a, 3602b and the residual dielectric spacers 3602c are removed. An appropriate etch process, such as a wet or dry etch and/or isotropic etch, may be implemented to remove the second gate dielectric spacers 3602a, 3602b and the residual dielectric spacers 3602c. In some examples, removal of the second gate dielectric spacers 3602a, 3602b and the residual dielectric spacers 3602c may be omitted. Further, in some examples, the second gate dielectric spacers 3602a, 3602b may remain, while the residual dielectric spacers 3602c are removed. In such cases, masking (e.g., by a photoresist) may permit removal of the residual dielectric spacers 3602c while the second gate dielectric spacers 3602a, 3602b remain.

A dielectric layer 3722 is formed over the semiconductor substrate 102, and contacts 3732, 3734, 3736, 3742, 3744 are formed through the dielectric layer 3722. The dielectric layer 3722 may include one or more dielectric sub-layers. For example, the dielectric layer 3722 may include a conformal first dielectric sub-layer over the semiconductor substrate 102 and a second dielectric sub-layer over the first dielectric sub-layer. The conformal first dielectric sub-layer may be a stressor layer, an etch stop layer, or the like, which may be or include silicon nitride, silicon oxynitride, the like, or a combination thereof. The second dielectric sub-layer may be or include silicon oxide, silicon nitride, or the like. The dielectric layer 3722 may be or include a pre-metal dielectric (PMD), an inter-layer dielectric (ILD), or the like. The dielectric layer 3722 may be deposited using CVD, PECVD, ALD, or the like. The dielectric layer 3722 may be planarized, such as by a CMP.

The contacts 3732, 3734, 3736, 3742, 3744 extend through the dielectric layer 3722 and contact respective metal-semiconductor compound 3702, 3704, 3706, 3712, 3714. The contacts 3732, 3734, 3736, 3742, 3744 may each include one or more barrier and/or adhesion layers (e.g., titanium nitride (TiN), tantalum nitride (TaN), the like, or a combination thereof) conformally in a respective opening through the dielectric layer 3722, and a fill metal (e.g., tungsten (W), copper (Cu), aluminum (Al), the like, or a combination thereof) over and/or on the barrier and/or adhesion layer(s).

To form the contacts 3732, 3734, 3736, 3742, 3744, respective openings may be formed through the dielectric layer 3722 to the metal-semiconductor compound 3702, 3704, 3706, 3712, 3714 using appropriate photolithography and etching processes. A metal(s) of the contacts 3732, 3734, 3736, 3742, 3744 are deposited in the openings through the dielectric layer 3722. The metal(s) may be deposited using an appropriate deposition process(es), such as CVD, PVD, or the like. Any excess metal(s) may be removed, such as by a CMP and/or by patterning using photolithography and etch processes.

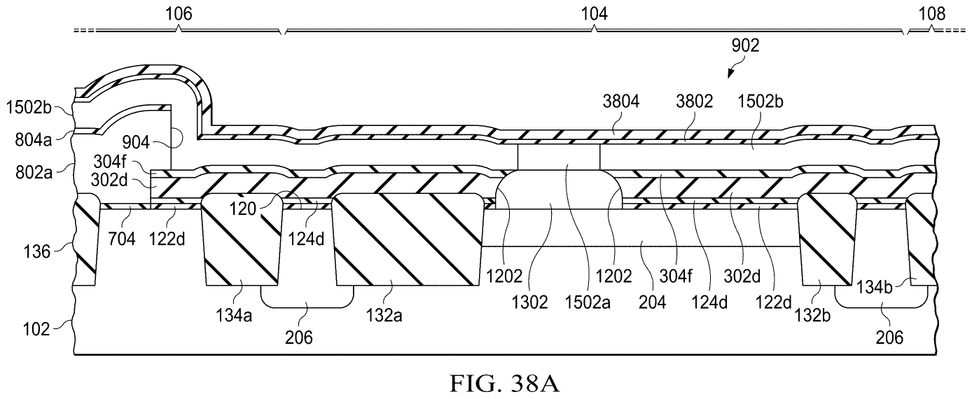

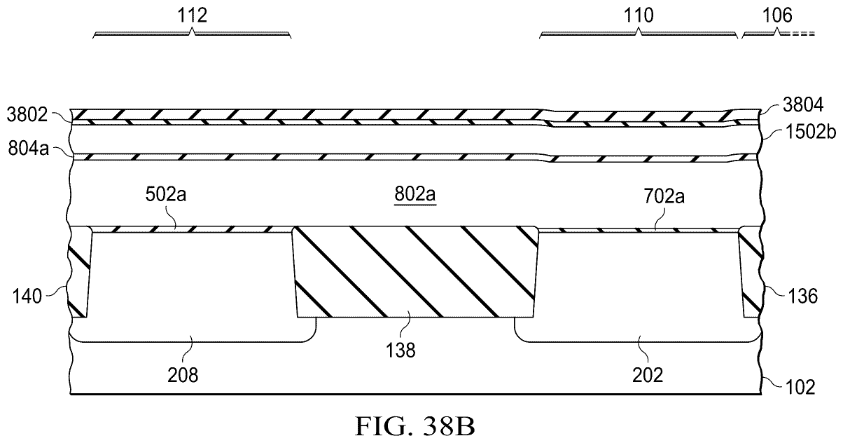

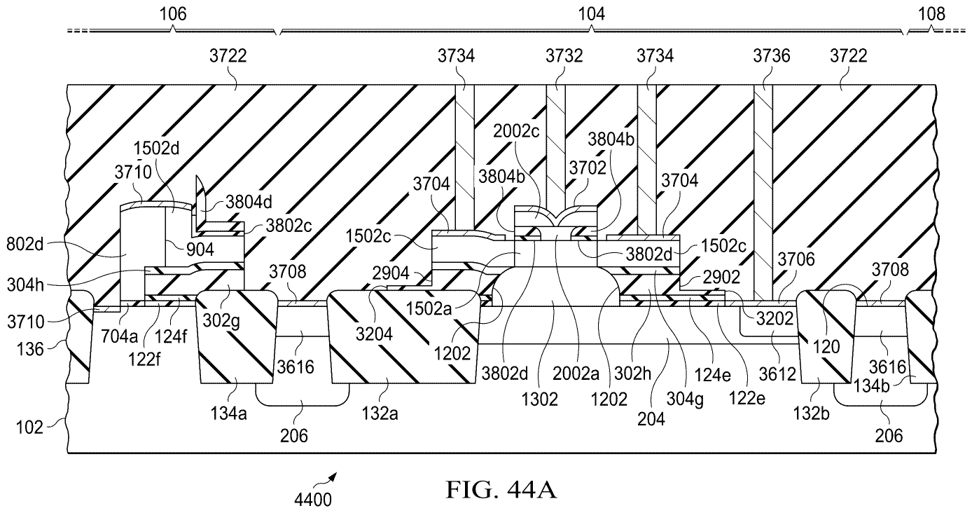

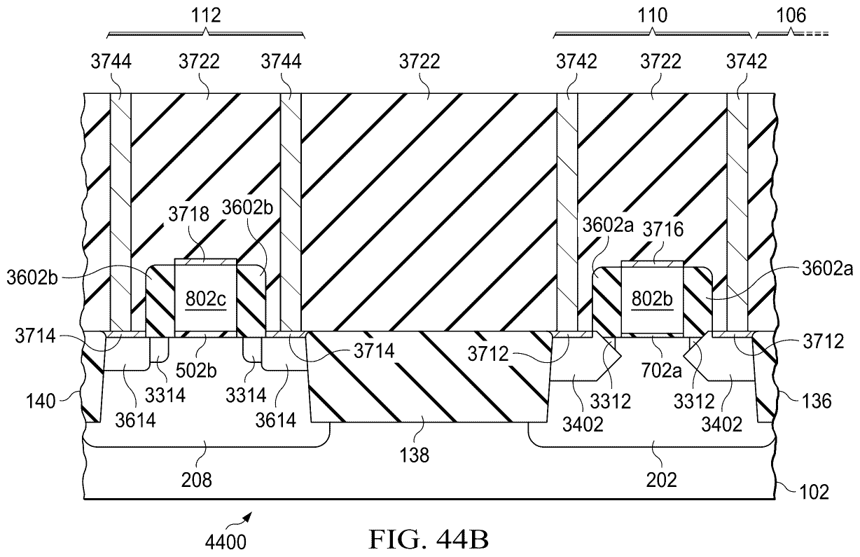

FIGS. 38A and 38B through FIGS. 44A and 44B are respective cross-sectional views of a semiconductor device in intermediate stages of manufacturing according to some examples. The method illustrated in these figures forms the semiconductor device 4400 of FIGS. 44A and 44B. Processing proceeds as described above with respect to FIGS. 1A and 1B through FIGS. 15A and 15B.

With reference to FIGS. 38A and 38B, a first dielectric spacer layer 3802 is formed conformally over the base layer 1502, and a second dielectric spacer layer 3804 is formed conformally over the first dielectric spacer layer 3802. In some examples, the second dielectric spacer layer 3804 is a dielectric material different from the dielectric material of the first dielectric spacer layer 3802. In some examples, the first dielectric spacer layer 3802 is silicon oxide (e.g., a TEOS oxide), and the second dielectric spacer layer 3804 is silicon nitride. The dielectric spacer layers 3802, 3804 may be deposited by CVD. Other dielectric materials and/or other deposition processes may be used in other examples.

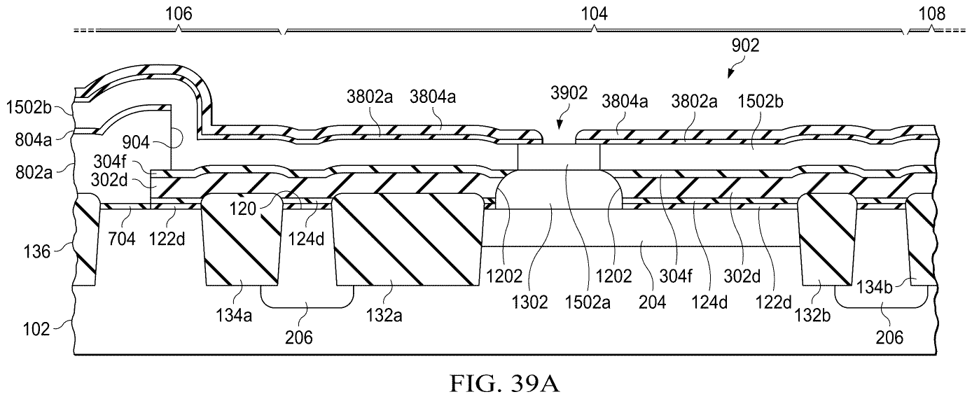

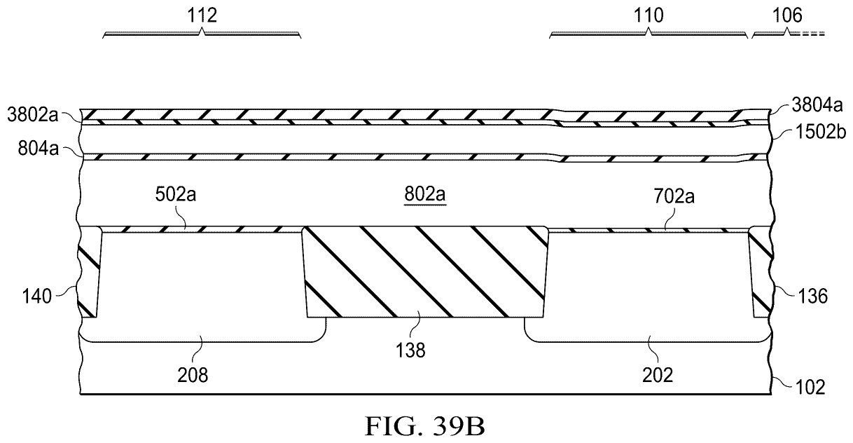

Referring to FIGS. 39A and 39B, the dielectric spacer layers 3802, 3804 are etched to form an emitter opening 3902 in the BJT region 104 through the first dielectric spacer layer 3802a and the second dielectric spacer layer 3804a. The monocrystalline base layer 1502a (of the base layer 1502) is exposed through the emitter opening 3902. The dielectric spacer layers 3802, 3804 may be patterned using appropriate photolithography and etch (e.g., RIE) processes.

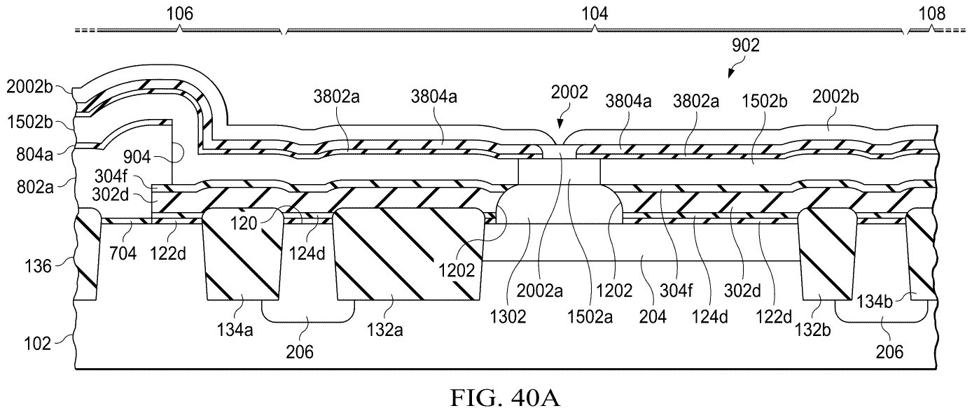

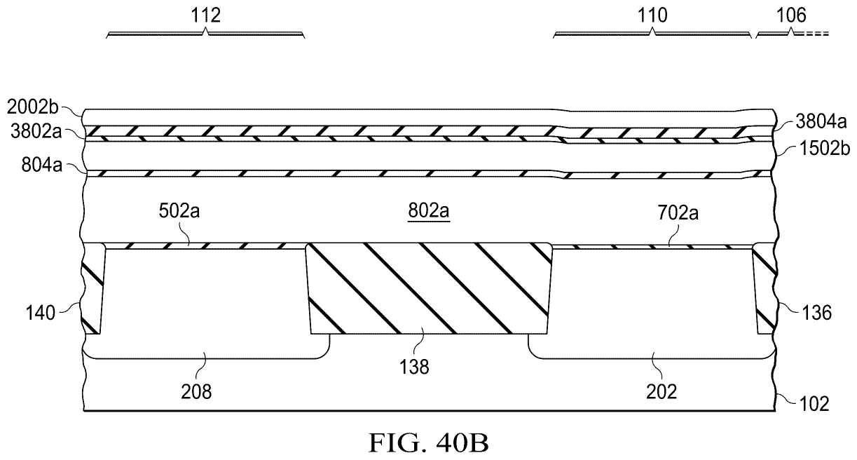

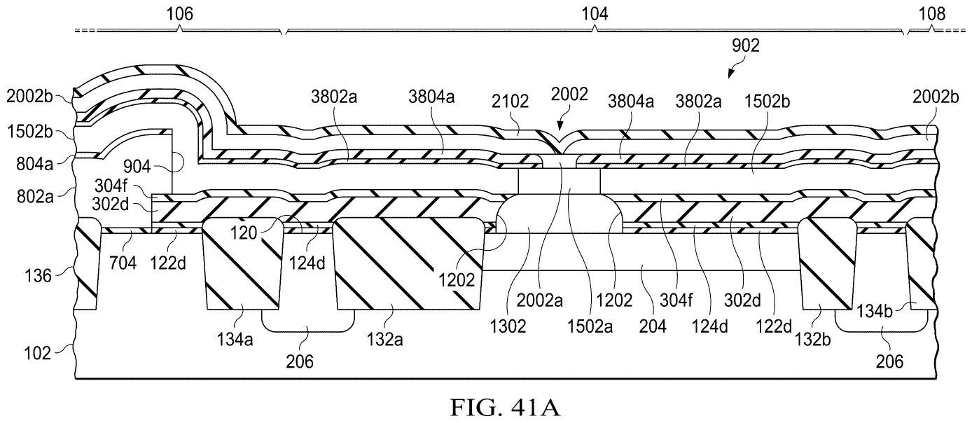

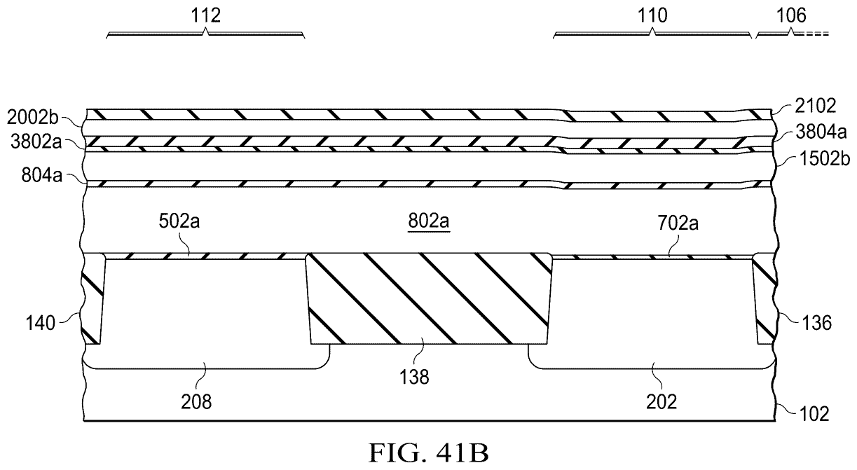

Referring to FIGS. 40A and 40B, an emitter layer 2002 is formed over the base layer 1502 (e.g., on the monocrystalline base layer 1502a) like described with respect to FIGS. 20A and 20B. The emitter layer 2002 may be epitaxially grown on the base layer 1502 (e.g., the monocrystalline base layer 1502a) exposed through the emitter opening 3902 and on the second dielectric spacer layer 3804a. Referring to FIGS. 41A and 41B, an emitter dielectric cap layer 2102 is conformally formed over the emitter layer 2002 like described with respect to FIGS. 21A and 21B.

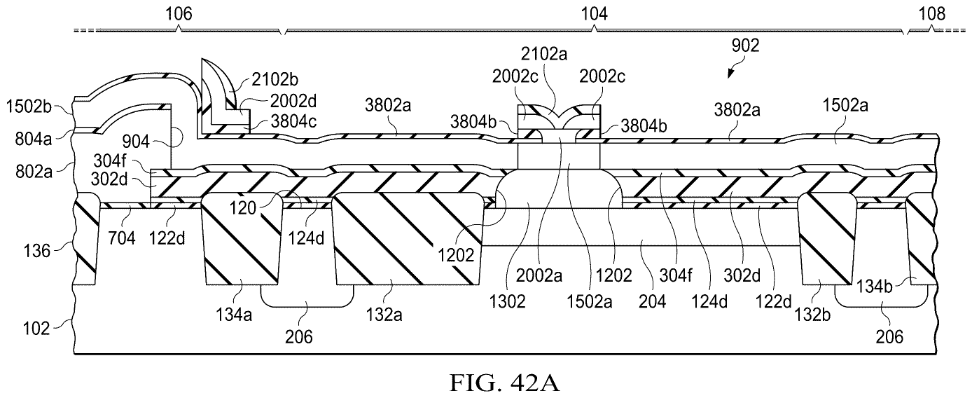

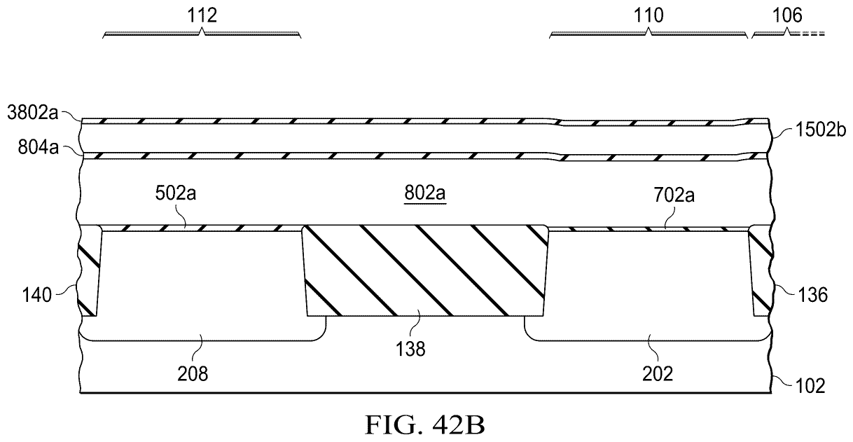

Referring to FIGS. 42A and 42B, the emitter dielectric cap layer 2102, the polycrystalline emitter layer 2002b, and the second dielectric spacer layer 3804a are patterned to form the emitter dielectric cap layer 2102a, polycrystalline emitter layer 2002c, and second dielectric spacer 3804b. The layers 2102, 2002b, 3804a may be patterned using appropriate photolithography and etch (e.g., RIE) processes. Residual emitter dielectric cap layer 2102b, residual polycrystalline emitter layer 2002d, and residual second dielectric spacer layer 3804c may remain, as illustrated, in the first transition region 106.

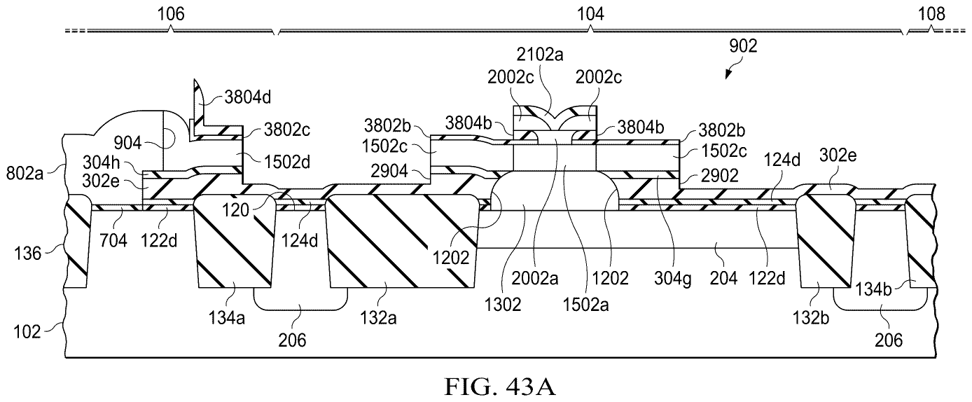

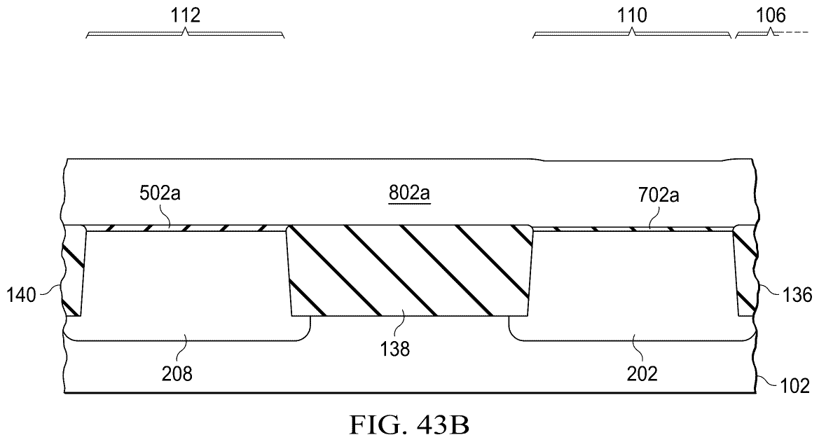

Referring to FIGS. 43A and 43B, the first dielectric spacer layer 3802a, the base layer 1502 (e.g., the polycrystalline base layer 1502b), and the fourth pedestal oxide sub-layer 304f are patterned in the BJT region 104. The first dielectric spacer layer 3802a, the polycrystalline base layer 1502b, and the fourth pedestal oxide sub-layer 304f are patterned to remain as the first dielectric spacer layer 3802b, the polycrystalline base layer 1502c, and the fourth pedestal oxide sub-layer 304g, respectively, in the BJT region 104. Further, the third pedestal oxide sub-layer 302d is thinned in areas where the first dielectric spacer layer 3802a, the polycrystalline base layer 1502b, and the fourth pedestal oxide sub-layer 304f are removed and results in the third pedestal oxide sub-layer 302e. Patterning the fourth pedestal oxide sub-layer 304f and thinning the third pedestal oxide sub-layer 302d results in sidewalls 2902, 2904 of the fourth and third pedestal oxide sub-layers 304g, 302e that align with respective sidewalls of the polycrystalline base layer. The layers 3802a, 1502b, 304f, 302d may be patterned or thinned using appropriate photolithography and etch (e.g., RIE) processes.

As illustrated, etching the first dielectric spacer layer 3802a and the polycrystalline base layer 1502b may remove the residual dielectric spacers 2102b, the dielectric protective layer 804a, and the residual polycrystalline emitter layer 2002d from the first transition region 106. Thereafter, etching the fourth and third pedestal oxide sub-layers 304f may remove any remaining residual dielectric spacers 2102b and dielectric protective layer 804a in the first transition region 106. Etching the fourth pedestal oxide sub-layer 304f results in a residual fourth pedestal oxide sub-layer 304h remaining in the first transition region 106. A residual polycrystalline base layer 1502d remains in the first transition region 106 along the sidewall 904 of the gate layer 802a and over the residual oxide layer 304h. The various etches may also reduce the residual second dielectric spacer layer 3804c such that residual second dielectric spacer layer 3804d remains over the residual polycrystalline base layer 1502d. Further, the various etches remove the first dielectric spacer layer 3802a, the polycrystalline base layer 1502b, and the dielectric protective layer 804a from the pFET region 110 and the nFET region 112.

Thereafter, processing continues as described with respect to FIGS. 30A and 30B through FIGS. 37A and 37B above. FIGS. 44A and 44B correspond with processing through the processing described with respect to FIGS. 37A and 37B. With respect to the formation of metal-semiconductor compound described above with respect to FIGS. 37A and 37B, metal-semiconductor compound 3704 is on the base layer 1502 (e.g., the polycrystalline base layer 1502c) in FIGS. 44A and 44B. The deposited metal is reacted with the semiconductor material of the base layer 1502 (e.g., the polycrystalline base layer 1502c). In processing to form the metal-semiconductor compound, the first dielectric spacer layer 3802b not underlying the second dielectric spacer 3804b may be removed, such as by a cleaning or etch process, which may cause a first dielectric spacer 3802d to remain under the second dielectric spacer 3804b.

FIGS. 37A and 37B illustrate a semiconductor device 3700, and FIGS. 44A and 44B illustrate a semiconductor device 4400. Each illustrated semiconductor device 3700, 4400 includes a BJT in the BJT region 104. The BJT includes the collector layer 1302, base layer 1502 (e.g., monocrystalline base layer 1502a and polycrystalline base layer 1502c), and emitter layer 2002 (e.g., monocrystalline emitter layer 2002a and polycrystalline emitter layer 2002b). The BJT of the semiconductor device 3700 of FIGS. 37A and 37B also includes a raised base layer 2702a on the base layer 1502 (e.g., on the polycrystalline base layer 1502c).

The collector layer 1302 is over (e.g., on) the upper surface 120 of the semiconductor substrate 102 and is through an opening in a pedestal dielectric stack that is over the upper surface of the semiconductor substrate 102. The pedestal dielectric stack (e.g., pedestal oxide stack) includes the first pedestal oxide sub-layer 122e over the upper surface 120, the second pedestal oxide sub-layer 124e over the first pedestal oxide sub-layer 122e, the third pedestal oxide sub-layer 302h over the second pedestal oxide sub-layer 124e, and the fourth pedestal oxide sub-layer 304g over the third pedestal oxide sub-layer 302h. The opening through the pedestal dielectric stack in which the collector layer 1302 is formed is defined, at least in part, by retrograde sidewalls 1202. The collector layer 1302 is on the n-type doped sub-collector diffusion region 204 in the semiconductor substrate 102. The base layer 1502 (e.g., the monocrystalline base layer 1502a) is over (e.g., on) the collector layer 1302, and the base layer 1502 (e.g., the polycrystalline base layer 1502c) is over (e.g., on) an upper surface of the fourth pedestal oxide sub-layer 304g.

The pedestal dielectric stack is in the BJT region 104 and underlies the base layer 1502. The portion of the pedestal dielectric stack directly underlying the base layer 1502 (e.g., including the pedestal oxide sub-layers 304g, 302h, 124c, 122c) has a first thickness. The pedestal dielectric stack (e.g., the fourth and third pedestal oxide sub-layers 304g, 302h) has sidewalls 2902, 2904 that align with respective sidewalls of the base layer 1502. The pedestal dielectric stack has the first thickness laterally between the sidewalls 2902, 2904. The pedestal dielectric stack (e.g., the third, second, and first pedestal oxide sub-layers 302h, 124c, 122c) extends laterally from the base layer 1502 (e.g., the polycrystalline base layer 1502c). For example, the pedestal dielectric stack extends over the upper surface 120 of the semiconductor substrate 102 over the n-type doped sub-collector diffusion region 204 and laterally away from a corresponding sidewall of the polycrystalline base layer 1502c (and the aligned sidewall 2902 of the pedestal dielectric stack) to the sidewall 3202 proximate the n-type collector contact region 3612. Additionally, the pedestal dielectric stack (e.g., the third pedestal oxide sub-layer 302g) extends over the first portion 132a of the isolation structure 132 laterally away from a corresponding sidewall of the polycrystalline base layer 1502c (and the aligned sidewall 2904 of the pedestal dielectric stack) to the sidewall 3204 over the first portion 132a of the isolation structure 132. The pedestal dielectric stack has a second thickness laterally between the sidewalls 2902, 3202, and the pedestal dielectric stack has a third thickness laterally between the sidewalls 2904, 3204. The second and third thicknesses of the pedestal dielectric stack are each less than the first thickness of the pedestal dielectric stack.

In some examples, the pedestal dielectric stack (e.g., pedestal oxide stack) may include nitrogen in a sub-layer and at an interface between that sub-layer and another sub-layer. For example, as described above, if the fourth pedestal sacrificial nitride sub-layer 304a is not fully oxidized by the oxidation processes of FIGS. 5A and 5B and FIGS. 7A and 7B, the fourth pedestal oxide sub-layer 304g may include nitrogen at the interface between the fourth pedestal oxide sub-layer 304g and the third pedestal oxide sub-layer 302h.

The emitter layer 2002 (e.g., the monocrystalline emitter layer 2002a) is over (e.g., on) the base layer 1502 (e.g., the monocrystalline base layer 1502a) and is through an opening defined by a spacer structure, and the emitter layer 2002 (e.g., the polycrystalline emitter layer 2002c) is over (e.g., on) the spacer structure. In the semiconductor device 3700 of FIGS. 37A and 37B, the spacer structure includes the second dielectric spacer 1604b, the third dielectric spacer 1606d, and emitter dielectric spacer 1802a. In the semiconductor device 4400 of FIGS. 44A and 44B, the spacer structure includes the first dielectric spacer 3802d and the second dielectric spacer 3804b.

The metal-semiconductor compound 3702 is on the emitter layer 2002 (e.g., the polycrystalline emitter layer 2002c and/or monocrystalline emitter layer 2002a). The metal-semiconductor compound 3706 is on the upper surface 120 of the semiconductor substrate 102 on the n-type collector contact region 3612. In the semiconductor device 3700 of FIGS. 37A and 37B, the metal-semiconductor compound 3704 is on the raised base layer 2702a. In the semiconductor device 4400 of FIGS. 44A and 44B, the metal-semiconductor compound 3704 is on the base layer 1502 (e.g., the polycrystalline base layer 1502c).

In some examples, the BJT may be a heterojunction BJT. As indicated previously, in some examples, the collector layer 1302 and the emitter layer 2002 may be silicon, and the base layer 1502 may include silicon germanium. Hence, in some examples, the base layer 1502 may include a semiconductor material dissimilar from respective semiconductor materials of the collector layer 1302 and emitter layer 2002. The dissimilar semiconductor materials may form one or more heterojunctions in the BJT, and the BJT may therefore be a heterojunction BJT.

Each illustrated semiconductor device 3700, 4400 includes a pFET in the pFET region 110 and an nFET in the nFET region 112. The pFET region 110 and nFET region 112 are in a CFET region. The pFET includes the gate electrode 802b, gate oxide layer 702a, embedded stressors 3402, PSD regions, p-type LDDs 3312, and a channel region in the semiconductor substrate 102 underlying the gate electrode 802b. The gate electrode 802b is over (e.g., on) the gate oxide layer 702a, and the gate oxide layer 702a is over (e.g., on) the upper surface 120 of the semiconductor substrate 102. The p-type LDDs 3312 are on laterally opposing sides of the gate electrode 802b and in the semiconductor substrate 102. The channel region is laterally between the p-type LDDs 3312. The embedded stressors 3402 and PSD regions are on laterally opposing sides of the gate electrode 802b, with the p-type LDDs 3312 and channel region therebetween. Similarly, the nFET includes the gate electrode 802c, gate oxide layer 502b, NSD regions 3614, n-type LDDs 3314, and a channel region in the semiconductor substrate 102 underlying the gate electrode 802c. The gate electrode 802c is over (e.g., on) the gate oxide layer 502b, and the gate oxide layer 502b is over (e.g., on) the upper surface 120 of the semiconductor substrate 102. The n-type LDDs 3314 are on laterally opposing sides of the gate electrode 802c and in the semiconductor substrate 102. The channel region is laterally between the n-type LDDs 3314. The NSD regions 3614 are on laterally opposing sides of the gate electrode 802c, with the n-type LDDs 3314 and channel region therebetween. The pFET and nFET may be complementary devices (e.g., complementary metal-oxide-semiconductor (CMOS) devices). In some examples, the pFET may be a p-type metal-oxide-semiconductor (PMOS) transistor, and the nFET may be an n-type metal-oxide-semiconductor (NMOS) transistor.

The first transition region 106 is between the BJT region 104 and the CFET region (e.g., with the CFET region having a boundary of the pFET region 110 in the illustrated examples). The second transition region 108 extends from a boundary of the BJT region 104 (e.g., opposite from the first transition region 106). A composite structure may remain in the first transition region 106 and/or second transition region 108. The composite structure may include respective residuals of various layers or materials formed during semiconductor processing and/or may be processing artifact(s). As illustrated in FIGS. 37A and 44A, the composite structure includes the residual gate layer 802d and the residual polycrystalline base layer 1502d on the sidewall 904 of the residual gate layer 802d. The composite structure also includes residual pedestal dielectric stack, including the residual pedestal oxide sub-layers 304h, 302g, 124f, 122f. In some examples, the residual pedestal dielectric stack may include nitrogen like described above with the pedestal dielectric stack formed with the BJT in the BJT region 104. For example, the residual fourth pedestal oxide sub-layer 304h may include nitrogen at the interface between the residual fourth pedestal oxide sub-layer 304h and the residual third pedestal oxide sub-layer 302g. Further, in some examples, the composite structure may include a residual polycrystalline emitter spacer. The composite structure may include one or more other residual dielectric spacers. In other examples, a composite structure including such residual spacers or residual layers may not be formed in the first transition region 106 and/or second transition region 108.

Although various examples have been described in detail, it should be understood that various changes, substitutions, and alterations can be made therein without departing from the scope defined by the appended claims.

What is claimed is:

1. A semiconductor device, comprising:
a semiconductor substrate;
a pedestal dielectric stack over the semiconductor substrate, the pedestal dielectric stack including nitrogen at an interface between a first sub-layer of the pedestal dielectric stack and a second sub-layer of the pedestal dielectric stack, an opening being through the pedestal dielectric stack to the semiconductor substrate, the opening being defined at least in part by a retrograde sidewall, the retrograde sidewall being retrograde into the pedestal dielectric stack from distal from the semiconductor substrate to proximate the semiconductor substrate; and
a bipolar junction transistor (BJT) on the semiconductor substrate, at least a first portion of the BJT being on an upper surface of the semiconductor substrate and in the opening through the pedestal dielectric stack, at least a second portion of the BJT further being over the pedestal dielectric stack.

2. The semiconductor device of claim 1, wherein the retrograde sidewall includes a sidewall portion having an upper overhang portion and a lower retrograde portion, a first dimension orthogonal to the upper surface of the semiconductor substrate being between the upper overhang portion and the lower retrograde portion, a second dimension parallel to the upper surface of the semiconductor substrate being between the upper overhang portion and the lower retrograde portion, a ratio of the first dimension to the second dimension being equal to or less than 1.376.

3. The semiconductor device of claim 1, wherein the pedestal dielectric stack includes:
a first pedestal oxide sub-layer over the semiconductor substrate; and
a second pedestal oxide sub-layer over the first pedestal oxide sub-layer, the second pedestal oxide sub-layer including the nitrogen, the interface being between the first pedestal oxide sub-layer and the second pedestal oxide sub-layer.

4. The semiconductor device of claim 1, wherein:
the BJT comprises:
a collector layer on the semiconductor substrate, the collector layer being in the opening through the pedestal dielectric stack;
a base layer on the collector layer, the base layer being over the pedestal dielectric stack; and
an emitter layer on the base layer.

5. A method, comprising:
forming a dielectric stack including:
forming a first oxide sub-layer over a semiconductor substrate;
depositing a sacrificial nitride sub-layer over the first oxide sub-layer; and
oxidizing the sacrificial nitride sub-layer, wherein oxidizing the sacrificial nitride sub-layer forms a second oxide sub-layer over the first oxide sub-layer; and
etching the dielectric stack with an etchant, etching the dielectric stack forms an opening through the dielectric stack to the semiconductor substrate, the opening being defined at least in part by a retrograde sidewall.

6. The method of claim 5, wherein the etchant laterally etches the first oxide sub-layer at a rate greater than a rate that the etchant laterally etches the second oxide sub-layer.

7. The method of claim 5, wherein the retrograde sidewall includes a sidewall portion having an upper overhang portion and a lower retrograde portion, a first dimension orthogonal to an upper surface of the semiconductor substrate being between the upper overhang portion and the lower retrograde portion, a second dimension parallel to the upper surface of the semiconductor substrate being between the upper overhang portion and the lower retrograde portion, a ratio of the first dimension to the second dimension being equal to or less than 1.376.

8. The method of claim 5, further comprising epitaxially growing a semiconductor material on the semiconductor substrate and in the opening.

9. The method of claim 5, wherein oxidizing the sacrificial nitride sub-layer also forms a gate oxide layer of a field effect transistor on the semiconductor substrate.

10. The method of claim 9, further comprising epitaxially growing a collector layer of a bipolar junction transistor on the semiconductor substrate and in the opening.

11. The method of claim 5, wherein:
forming the first oxide sub-layer includes:
performing an oxidation process on the semiconductor substrate to form the first oxide sub-layer; and
implanting dopants into the semiconductor substrate through the first oxide sub-layer, implanting the dopants damaging the first oxide sub-layer;
forming the dielectric stack further includes depositing a third oxide sub-layer over the first oxide sub-layer, the sacrificial nitride sub-layer being deposited over the third oxide sub-layer; and
during etching the dielectric stack with the etchant, a lateral etch rate of the first oxide sub-layer to the etchant is greater than a lateral etch rate of the third oxide sub-layer to the etchant, and the lateral etch rate of the third oxide sub-layer to the etchant is greater than a lateral etch rate of the second oxide sub-layer to the etchant.

12. A method, comprising:
forming a dielectric stack including:
forming a first dielectric sub-layer over a semiconductor substrate;
depositing a second dielectric sub-layer over the first dielectric sub-layer, the second dielectric sub-layer including nitrogen; and
treating the second dielectric sub-layer such that a lateral etch rate of the second dielectric sub-layer to an etchant is less than a lateral etch rate of the first dielectric sub-layer to the etchant; and
forming an opening through the dielectric stack, forming the opening including etching the dielectric stack using the etchant.

13. The method of claim 12, wherein the opening is defined at least in part by a retrograde sidewall.

14. The method of claim 13, wherein the retrograde sidewall includes a sidewall portion having an upper overhang portion and a lower retrograde portion, a first dimension orthogonal to an upper surface of the semiconductor substrate being between the upper overhang portion and the lower retrograde portion, a second dimension parallel to the upper surface of the semiconductor substrate being between the upper overhang portion and the lower retrograde portion, a ratio of the first dimension to the second dimension being equal to or less than 1.376.

15. The method of claim 12, wherein treating the second dielectric sub-layer includes performing an oxidation process.

16. The method of claim 15, wherein the oxidation process further forms a gate oxide layer of a field effect transistor on the semiconductor substrate.

17. The method of claim 16, further comprising epitaxially growing a collector layer of a bipolar junction transistor on the semiconductor substrate and in the opening.

18. The method of claim 12, wherein treating the second dielectric sub-layer outgasses at least some of the nitrogen.

19. The method of claim 12, wherein:
the first dielectric sub-layer is an oxide layer;
the second dielectric sub-layer, as deposited, is a nitride layer; and
treating the second dielectric sub-layer oxidizes the second dielectric sub-layer.

20. The method of claim 19, wherein:
forming the first dielectric sub-layer includes:
performing an oxidation process on the semiconductor substrate to form the first dielectric sub-layer; and
implanting dopants into the semiconductor substrate through the first dielectric sub-layer, implanting the dopants damaging the first dielectric sub-layer;
forming the dielectric stack further includes depositing a third dielectric sub-layer over the first dielectric sub-layer, the third dielectric sub-layer being an oxide layer, the second dielectric sub-layer being deposited over the third dielectric sub-layer; and
after treating the second dielectric sub-layer, the lateral etch rate of the second dielectric sub-layer to the etchant is less than a lateral etch rate of the third dielectric sub-layer to the etchant, and the lateral etch rate of the third dielectric sub-layer to the etchant is less than a lateral etch rate of the first dielectric sub-layer to the etchant.
